(19) United States
(12) Patent Application Publication
(10) Pub. No.: US 2026/0314444 A1
(43) Pub. Date: Oct. 8, 2026

(54) CIRCUIT BOARD AND SEMICONDUCTOR PACKAGE SUBSTRATE COMPRISING SAME

(71) Applicant: LG INNOTEK CO., LTD., Seoul (KR)

(72) Inventors: Dae Hyeon SEONG, Seoul (KR); Yong Seok NA, Seoul (KR)

(21) Appl. No.: 19/478,933

(22) PCT Filed: Apr. 29, 2024
(86) PCT No.: PCT/KR2024/005763

§ 371 Date: Oct. 27, 2025

(30) Foreign Application Priority Data
Apr. 28, 2023 (KR) 10-2023-0056070

(51) Int. Cl. H10W 70/63; H10W 70/685

(52) U.S. Cl. CPC H10W 70/635; H10W 70/685

(57) ABSTRACT

A circuit board according to an embodiment includes a core insulating layer including an upper surface and a lower surface; an upper insulating layer disposed on the core insulating layer; a lower insulating layer disposed under the core insulating layer; and a through electrode penetrating the upper and lower surfaces of the core insulating layer, wherein the through electrode includes a first through part disposed adjacent to the upper surface of the core insulating layer and having a first slope whose width gradually decreases toward the lower surface of the core insulating layer; and a second through part disposed adjacent to the lower surface of the core insulating layer and having a second slope whose width gradually decreases toward the upper surface of the core insulating layer, wherein a vertical length of the first slope is different from a vertical length of the second slope, and a difference between a width of an upper surface of the first through part and a width of a lower surface of the second through part is smaller than a difference between the vertical length of the first slope and the vertical length of the second slope.

### TECHNICAL FIELD

The embodiment relates to a circuit board, and more particularly to a circuit board having a core insulating layer and a semiconductor package substrate including the same.

### BACKGROUND ART

As performances of electric/electronic products progresses, technologies for disposing a greater number of semiconductor devices on a semiconductor package circuit board of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

In addition, semiconductor packages applied to products that provide the Internet of Things (IoT), autonomous vehicles, and high-performance servers are expanding a concept to semiconductor chiplets as a number of semiconductor devices and/or a size of each semiconductor device increases in accordance with a trend of high integration, or as functional parts of the semiconductor devices are divided.

As a result, mutual communication between semiconductor devices and/or semiconductor chiplets is becoming more important, and accordingly, an area and/or thickness of the semiconductor package is increasing as a number of semiconductor devices and/or semiconductor chiplets disposed on the semiconductor package increases, or wiring for electrical connection with semiconductor devices and/or semiconductor chiplets increases.

An interposer may be disposed between the semiconductor package and the semiconductor device and/or semiconductor chiplet. The interposer can function as a redistribution layer that gradually increases a width or breadth of the circuit pattern as it goes from the semiconductor device to the semiconductor package to facilitate mutual communication between semiconductor devices and/or semiconductor chiplets, or to interconnect semiconductor devices and semiconductor package substrates. Accordingly, the interposer can function to smoothly transmit electrical signals between the semiconductor package substrate and the semiconductor device with a relatively large circuit pattern compared to the circuit pattern of the semiconductor device.

The interposer may have an area larger than a total area of a plurality of semiconductor devices and/or semiconductor chiplets to mount the plurality of semiconductor devices and/or semiconductor chiplets as a whole, or may be disposed only in a portion for interconnection between the semiconductor devices and/or semiconductor chiplets. In other words, the area of the interposer may increase as the number of semiconductor devices and/or semiconductor chiplets increases. Therefore, as the number of semiconductor devices and/or semiconductor chiplets increases, the area of the semiconductor package substrate tends to increase.

At this time, there is a problem that the semiconductor package is more warped as the area and/or thickness of the semiconductor package and/or interposer increases. Therefore, the semiconductor package and/or interposer include a core insulating layer with a reinforcement member to ensure rigidity. Furthermore, as the area of the semiconductor package and/or interposer increases, a thickness of the core insulating layer may also increase. For example, a thickness of the core insulating layer may exceed 100 μm, 150 μm, 200 μm, or 250 μm.

In this case, as the thickness of the core insulating layer increases, physical and/or electrical reliability of a through electrode penetrating the core insulating layer may deteriorate. For example, when plating a through electrode in a through hole formed in a core insulating layer having a thickness greater than a certain level, differences in plating speed between regions in a vertical direction of the through hole may occur, and as a result, at least a portion of the through hole may not be filled with a conductive material, or a concave portion may be formed on upper and/or lower surfaces of the through electrode. If at least a portion of the through hole is not filled with a conductive material, the rigidity of the through electrode may deteriorate, and cracks may occur in the through electrode due to stress caused by heat cycles resulting from expansion and/or contraction. In addition, if a concave part is provided on the upper and/or lower surface of the through electrode, a flatness of the insulating layer and/or electrode part provided on an upper and/or lower side of the core insulating layer may be reduced, and thus the semiconductor device may not be stably mounted.

### DISCLOSURE

### Technical Problem

An embodiment provides a circuit board including a through electrode having a new structure and a semiconductor package substrate including the same.

In addition, the embodiment provides a circuit board with improved physical and/or electrical reliability and a semiconductor package substrate including the same.

In addition, the embodiment provides a circuit board with improved rigidity and a semiconductor package substrate including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a core insulating layer including an upper surface and a lower surface; an upper insulating layer disposed on the core insulating layer; a lower insulating layer disposed under the core insulating layer; and a through electrode penetrating the upper and lower surfaces of the core insulating layer, wherein the through electrode includes: a first through part disposed adjacent to the upper surface of the core insulating layer and having a first slope whose width gradually decreases toward the lower surface of the core insulating layer; and a second through part disposed adjacent to the lower surface of the core insulating layer and having a second slope whose width gradually decreases toward the upper surface of the core insulating layer, wherein a vertical length of the first slope is different from a vertical length of the second slope, and a difference between a width of an upper surface of the first through part and a width of a lower surface of the second through part is smaller than a difference between the vertical length of the first slope and the vertical length of the second slope.

Meanwhile, a circuit board according to an embodiment comprises a core insulating layer including an upper surface and a lower surface, and a through hole penetrating the upper and lower surfaces; an upper insulating layer disposed on the core insulating layer; and a lower insulating layer disposed under the core insulating layer; wherein the through hole includes: a first hole part disposed adjacent to the upper surface of the core insulating layer and having a first slope whose width gradually decreases toward the lower surface of the core insulating layer; and a second hole part disposed adjacent to the lower surface of the core insulating layer and having a second slope whose width gradually decreases toward the upper surface of the core insulating layer, wherein a vertical length of the first slope is different from a vertical length of the second slope, and a difference between a width of the first hole part at an upper end of the first slope and a width of the second hole part at a lower end of the second slope is smaller than a difference between the vertical length of the first slope and the vertical length of the second slope.

In addition, the circuit board further comprises a through electrode penetrating the upper and lower surfaces of the core insulating layer and disposed in the through hole of the core insulating layer, wherein the through electrode includes: a first through part disposed in the first hole part and having the first slope; and a second through part disposed in the second hole part and having the second slope, wherein the width of the first hole part at the upper end of the first slope is a width of an upper surface of the first through part, and the width of the second hole part at the lower end of the second slope is a width of a lower surface of the second through part.

In addition, the width of the lower surface of the first through part is the same as the width of the upper surface of the second through part.

In addition, a slope angle of the first slope and a slope angle of the second slope are not constant, and the vertical length of the first slope is greater than the vertical length of the second slope.

In addition, a region where the first slope of the first through part and the second slope of the second through part meet is closer to the lower surface of the core insulating layer than to the upper surface of the core insulating layer.

In addition, a ratio of the vertical length of the first slope to the vertical length of the second slope is 7:3 to 8:2.

In addition, the core insulating layer is an insulating layer having a largest thickness among a plurality of insulating layers.

In addition, the core insulating layer has a thickness in a range of 100 μm to 700 μm.

In addition, the core insulating layer includes a reinforcement member.

In addition, a horizontal distance between an upper end of the first slope at one side of the through electrode and a lower end of the second slope at one side of the through electrode is smaller than a vertical distance from a center horizontal line between the upper and lower surfaces of the through electrode to a region where the first slope and the second slope meet.

In addition, the through electrode has a smallest width in a region where the first slope of the first through part and the second slope of the second through part meet.

In addition, a difference between widths of upper and lower surfaces of the first through part and a difference between widths of upper and lower surfaces of the second through part is smaller than the vertical distance from the center horizontal line between the upper and lower surfaces of the through electrode to the region where the first slope and the second slope meet.

In addition, the first slope and the second slope are inclined in different directions.

In addition, the circuit board further comprises an upper through electrode penetrating the upper insulating layer; and a lower through electrode penetrating the lower insulating layer, wherein the upper through electrode has a third slope whose width gradually decreases from an upper surface of the upper insulating layer toward a lower surface of the upper insulating layer, and the lower through electrode has a fourth slope whose width gradually decreases from a lower surface of the lower insulating layer toward an upper surface of the lower insulating layer.

In addition, the circuit board further includes a connection member embedded in the upper insulating layer, wherein the connection member includes at least one of an inorganic bridge and an organic bridge.

In addition, the circuit board further includes a plurality of semiconductor devices disposed on the upper insulating layer, wherein at least a portion of each of the plurality of semiconductor devices overlaps the connection member in a vertical direction.

Meanwhile, a circuit board according to another embodiment comprises a core insulating layer including an upper surface and a lower surface; an upper insulating layer disposed on the upper surface of the core insulating layer; a lower insulating layer disposed on the lower surface of the core insulating layer; and a through electrode penetrating the upper and lower surfaces of the core insulating layer, wherein the through electrode includes a first slope disposed adjacent to the upper surface of the core insulating layer and having a width that gradually decreases toward the lower surface of the core insulating layer, and a second slope disposed adjacent to the lower surface of the core insulating layer and having a width that gradually decreases toward the upper surface of the core insulating layer, wherein a vertical length of the first slope is different from a vertical length of the second slope, and the through electrode includes a first through electrode having a vertical length of the first slope greater than a vertical length of the second slope, and a second through electrode having a vertical length of the first slope smaller than a vertical length of the second slope and spaced apart from the first through electrode in a horizontal direction.

In addition, one of the first and second through electrodes is provided in a plurality of numbers in an inner region of the core insulating layer, and the other one of the first and second through electrodes is provided in a plurality of numbers in an outer region surrounding the inner region of the core insulating layer along a circumferential direction of the upper surface of the core insulating layer.

### Advantageous Effects

A circuit board of an embodiment includes an insulating layer and a through electrode penetrating the insulating layer. The insulating layer may be a core insulating layer including a reinforcement member, and the through electrode is provided to penetrate upper and lower surfaces of the core insulating layer.

The through electrode includes a first through part adjacent to the upper surface of the insulating layer and having a first slope whose width gradually decreases toward the lower surface of the insulating layer, and a second through part adjacent to the lower surface of the insulating layer and having a second slope whose width gradually decreases toward the upper surface of the insulating layer. The first and second slopes may have slopes that are inclined in different directions along a vertical direction from the upper surface of the insulating layer toward the lower surface. Therefore, the embodiment can improve plating processability of the through electrode compared to a through electrode whose width does not change from the upper surface of the insulating layer toward the lower surface, thereby improving product yield.

As the number of semiconductor devices and/or semiconductor chiplets mounted on the circuit board increases, the area and/or thickness of the circuit board may also increase. Accordingly, a thickness of the insulating layer corresponding to the core insulating layer may increase. However, if the thickness of the core insulating layer increases, a width of a center region where the first and second slopes of the through electrode meet may be too large or too small, which may deteriorate the plating process performance.

Therefore, the embodiment improves the plating process performance in a process of plating the through electrode by ensuring that the vertical lengths of the first and second slopes of the through electrode are different from each other and further adjusting a ratio of vertical lengths of the first and second slopes.

In particular, the embodiment ensures that a ratio of the vertical lengths of the first and second slopes satisfies a range of 7:3 to 8:2. Through this, the embodiment can solve a void problem that may occur due to the width of the center region where the first slope and the second slope meet being too small. In addition, the embodiment can solve a problem of flatness in which a surface of the pad is concave because a width of the center region where the first slope and the second slope meet is too large.

Therefore, the embodiment can improve the process capability in the plating process of the through electrode by ensuring that a ratio of the vertical length of the first slope to the vertical length of the second slope satisfies a range of 7:3 to 8:2, thereby reducing the manufacturing time and improving the product yield. In addition, the embodiment can prevent the formation of voids within the through electrode, thereby preventing cracks in the through electrode due to stress caused by heat cycles, thereby improving the physical reliability of the circuit board. In addition, the embodiment can ensure the flatness of the through electrode and pad, thereby allowing the semiconductor device to be stably disposed on the circuit board. Accordingly, the embodiment can allow the semiconductor device to operate stably, and can improve the operational reliability of the semiconductor package and a product to which the semiconductor package is applied.

In addition, the through electrode can have a first width at an upper end of the first slope and a second width at a lower end of the second slope. The first width can refer to a width of an upper surface of the through electrode, and the second width can refer to a width of a lower surface of the through electrode. In addition, the through electrode may have a third width smaller than the first and second widths in a region where the first and second slopes meet.

At this time, the embodiment controls a difference between the first and second widths to improve process capability in the plating process of the through electrode and reduce the resistance of the through electrode, thereby improving electrical characteristics.

For example, a difference between the first and second widths in the embodiment may be smaller than a difference between the vertical length of the first slope and the vertical length of the second slope. For example, the difference between the first and third widths and the difference between the second and third widths in the embodiment may be smaller than the difference between the vertical lengths of the first slope and the second slope. Furthermore, the difference between the first and second widths in the embodiment may be smaller than a vertical length from a center horizontal line between upper and lower surfaces of the through electrode to a region where the first and second slopes meet. In addition, a horizontal distance between an upper end of the first slope at one side of the through electrode and a lower end of the second slope at one side of the through electrode may be smaller than the vertical distance from the center horizontal line to the region where the first and second slopes meet.

Accordingly, the embodiment can improve the flatness deterioration of upper and/or lower surfaces of a pad caused by the difference between the first and second widths not satisfying the conditions. Furthermore, the embodiment can reduce the resistance of the first through electrode, thereby improving the electrical characteristics of the circuit board and semiconductor package.

In addition, the embodiment can adjust the vertical lengths of the first and second slopes based on a direction in which the circuit board is warped. For example, the embodiment may allow the vertical length of the first slope to be greater than the vertical length of the second slope when the circuit board is warped in a smile shape such as a ‘∪’. For example, the embodiment may allow the vertical length of the second slope to be greater than the vertical length of the first slope when the circuit board is warped in a crying shape such as a ‘∩’.

The embodiment may determine a slope having a larger vertical length among the first slope and the second slope of the through electrode according to a warpage direction of the circuit board, thereby preventing the semiconductor package from being greatly warped in a specific direction.

### DESCRIPTION OF DRAWINGS

FIG. 1a is a cross-sectional view showing a semiconductor package according to a first embodiment.

FIG. 1b is a cross-sectional view showing a semiconductor package according to a second embodiment.

FIG. 1c is a cross-sectional view showing a semiconductor package according to a third embodiment.

FIG. 1d is a cross-sectional view showing a semiconductor package according to a fourth embodiment.

FIG. 1e is a cross-sectional view showing a semiconductor package according to a fifth embodiment.

FIG. 1f is a cross-sectional view showing a semiconductor package according to a sixth embodiment.

FIG. 1g is a cross-sectional view showing a semiconductor package according to a seventh embodiment.

FIG. 2 is a cross-sectional view illustrating a circuit board according to a first embodiment.

FIG. 3 is a cross-sectional view illustrating a through hole provided in a first insulating layer of FIG. 2.

FIG. 4 (a) and (b) is a cross-sectional view illustrating a process for forming a through hole in a core insulating layer according to a comparative example.

FIG. 5 (a) and (b) is a cross-sectional view illustrating a through hole provided in a core insulating layer according to a comparative example.

FIG. 6 is a cross-sectional view illustrating a through electrode provided in the first insulating layer of FIG. 2.

FIG. 7 (a) and (b) is a cross-sectional view illustrating a through hole and a through electrode according to a second embodiment.

FIG. 8 is a cross-sectional view illustrating a circuit board according to a third embodiment.

FIG. 9 is a plan view illustrating a first through electrode provided in the first insulating layer of FIG. 8.

FIGS. 10 to 17 are cross-sectional views showing a method for manufacturing the circuit board shown in FIG. 2 in order of processes.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### Electronic Device

Before describing the embodiment, an electronic device to which the semiconductor package of the embodiment is applied will be briefly described. The electronic device includes a main board (not shown). The main board may be connected to the semiconductor package of the embodiment. The semiconductor package may include at least one semiconductor device.

The semiconductor device may be a logic chip, a memory chip, etc. The logic chip may be a central processor (CPU), a graphics processor (GPU), etc. For example, the logic chip may include an application processor (AP) including at least one of a central processor (CPU), a graphics processor (GPU), a digital signal processor, a cryptographic processor, a microprocessor, a microcontroller, or may include an analog-to-digital converter, an application-specific IC (ASIC), etc., or may be a chip set including a specific combination of the above. The memory chip may be a stacked memory such as HBM, or may include a volatile memory (e.g., DRAM), a non-volatile memory (e.g., ROM), a flash memory, etc.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later. In addition, the semiconductor package according to the embodiment should be understood as an interposer as well as a semiconductor package.

In addition, a circuit board in one embodiment may be a first circuit board described below. In addition, the circuit board in another embodiment may be a second circuit board described below.

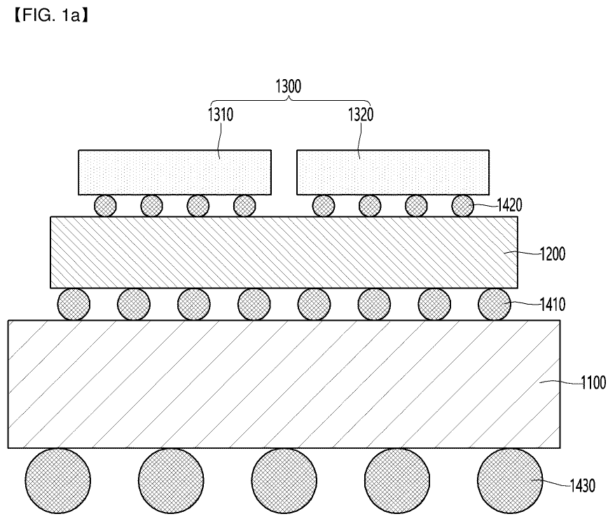

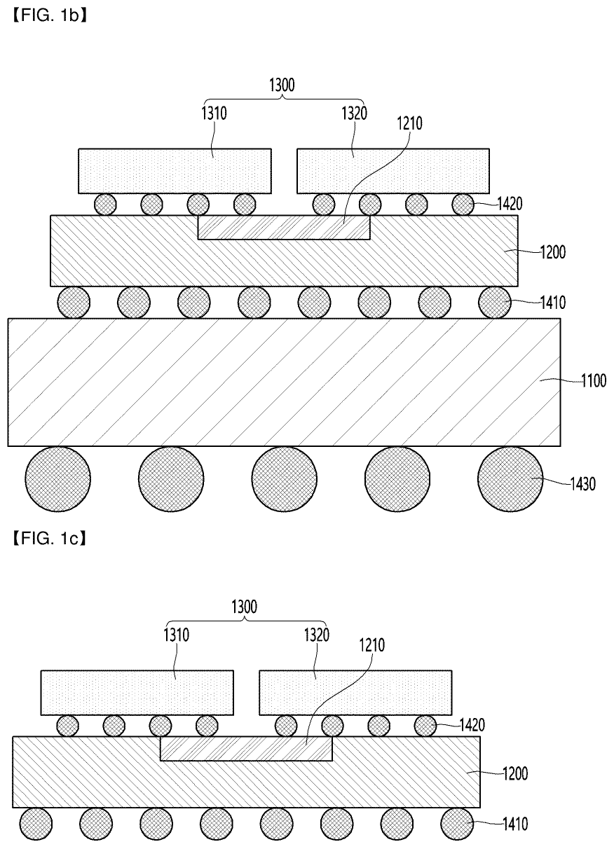

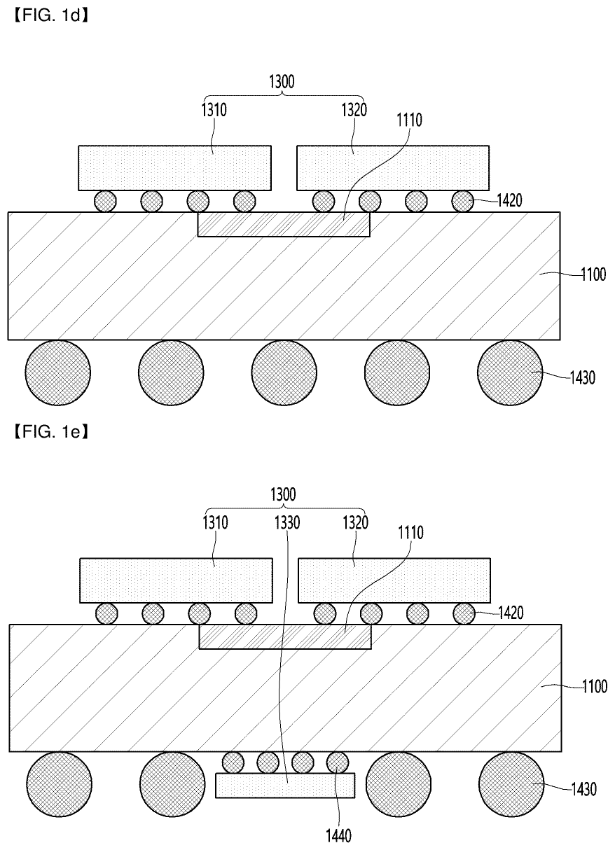

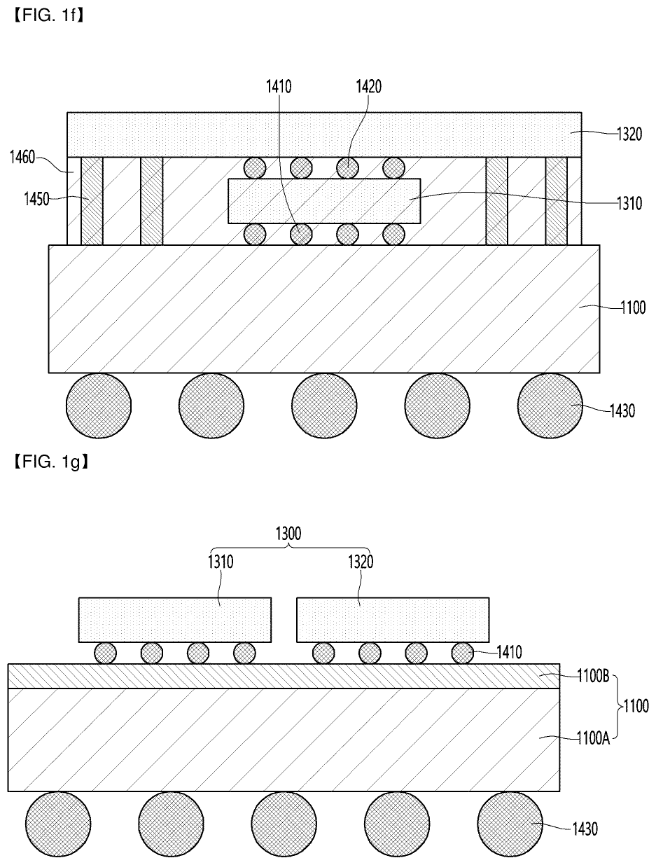

FIG. 1a is a cross-sectional view showing a semiconductor package according to a first embodiment, FIG. 1b is a cross-sectional view showing a semiconductor package according to a second embodiment, FIG. 1c is a cross-sectional view showing a semiconductor package according to a third embodiment, FIG. 1d is a cross-sectional view showing a semiconductor package according to a fourth embodiment, FIG. 1e is a cross-sectional view showing a semiconductor package according to a fifth embodiment, FIG. 1f is a cross-sectional view showing a semiconductor package according to a sixth embodiment, and FIG. 1g is a cross-sectional view showing a semiconductor package according to a seventh embodiment.

Referring to FIG. 1a, the semiconductor package according to the first embodiment may include a first circuit board 1100, a second circuit board 1200, and a semiconductor device 1300.

The first circuit board 1100 may mean a package substrate.

For example, the first circuit board 1100 may provide a space to which at least one external circuit board is coupled. The external circuit board may refer to a second circuit board 1200 coupled to the first circuit board 1100. Also, the external circuit board may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 may include at least one insulating layer, an electrode part disposed on the at least one insulating layer.

A second circuit board 1200 may be disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package substrate.

FIG. 1a illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one semiconductor device 1300 and the first circuit board 1100.

In an embodiment, the second circuit board 1200 may be an active interposer that functions as a semiconductor device. When the second circuit board 1200 functions as a semiconductor device, the semiconductor package of the embodiment may have a structure that is vertically stacked on the first circuit board 1100 and may have functions of multiple logic chips. Having the function of a logic chip may mean that it may have functions of an active device and a passive device. In a case of an active device, characteristics of current and voltage may not be linear unlike a passive device, and in a case of an active interposer, it may have the function of an active device. In addition, the active interposer may perform a function of a corresponding logic chip while performing a signal transmission function between a second logic chip disposed thereon and the first circuit board 1100.

According to another embodiment, the second circuit board 1200 may be a passive interposer. For example, the second circuit board 1200 may function as a signal relay between the semiconductor device 1300 and the first circuit board 1100, and can have a passive device function such as a resistor, capacitor, or inductor. For example, a number of terminals of the semiconductor device 1300 is gradually increasing due to 5G, Internet of Things (IOT), increased image quality, and increased communication speed. That is, the number of terminals provided in the semiconductor device 1300 increases, thereby reducing the width of the terminals or an interval between the plurality of terminals. In this case, the first circuit board 1100 may be connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 may be disposed on the first circuit board 1100 and the semiconductor device 1300. In addition, the second circuit board 1200 may include electrodes having a fine width and an interval corresponding to the terminals of the semiconductor device 1300.

The semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment may include a connection part.

For example, the semiconductor package may include a first connection part 1410 disposed between the first circuit board 1100 and the second circuit board 1200. The first connection part 1410 may electrically connect the second circuit board 1200 to the first circuit board 1100 while coupling them.

For example, the semiconductor package may include the second connection part 1420 disposed between the second circuit board 1200 and the semiconductor device 1300. The second connection part 1420 may electrically connect the semiconductor device 1300 to the second circuit board 1200 while coupling them.

The semiconductor package may include a third connection part 1430 disposed on a lower surface of the first circuit board 1100. The third connection part 1430 may electrically connect the first circuit board 1100 to the main board while coupling them.

At this time, the first connection part 1410, the second connection part 1420, and the third connection part 1430 may electrically connect between the plurality of components by using at least one bonding method of wire bonding, solder bonding and metal-to-metal direct bonding. That is, since the first connection part 1410, the second connection part 1420, and the third connection part 1430 have a function of electrically connecting a plurality of components, when the metal-to-metal direct bonding is used, the connection part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. In addition, to directly bond between the plurality of components. In addition, the metal-to-metal direct bonding method may refer to a bonding method by the second connection part 1420. In this case, the second connection part 1420 may mean a metal layer formed between a plurality of components by the recrystallization.

Specifically, the first connection part 1410, the second connection part 1420, and the third connection part 1430 may couple a plurality of components to each other by a thermal compression (TC) bonding method. The thermal compression bonding may refer to a method of directly coupling a plurality of components by applying heat and pressure to the first connection part 1410, the second connection part 1420, and the third connection part 1430.

At this time, at least one of the first circuit board 1100 and the second circuit board 1200 may be provided with a protrusion that protrudes outwardly away from the insulating layer of the corresponding board, on which the first connection part 1410, the second connection part 1420, and the third connection part 1430 are disposed. The protrusion may protrude outwardly from the first circuit board 1100 or the second circuit board 1200.

The protrusion may refer to an electrode on which a second connection part 1420 for coupling with the semiconductor device 1300 is disposed among the electrodes of the second circuit board 1200. That is, as the pitch of the terminals of the semiconductor device 1300 becomes finer, a short circuit may occur between the plurality of second connection parts 1420 that are respectively connected to the plurality of terminals of the semiconductor device 1300 by a conductive adhesive such as a solder. Therefore, in the embodiment, thermal compression bonding may be performed to reduce a volume of the second connection part 1420. In addition, in order to secure diffusion prevention and alignment to prevent an intermetallic compound (IMC) formed between a conductive adhesive such as solder and a protrusion from diffusing into the interposer and/or the circuit board, a protrusion may be included in the electrode of the second circuit board 1200 on which the second connection part 1420 is disposed.

Meanwhile, referring to FIG. 1b, the semiconductor package of the second embodiment may differ from the semiconductor package of the first embodiment in that the connection member 1210 is disposed on the second circuit board 1200. The connection member 1210 may be referred to as a bridge circuit board. For example, the connection member 1210 may include a redistribution layer. The connection member 1210 may perform a function of electrically connecting a plurality of semiconductor devices horizontally to each other. For example, since the area that a semiconductor device should generally have been too large, the connection member 1210 may include a redistribution layer. Since the semiconductor package and the semiconductor device have a large difference in a width or spacing of the circuit pattern, etc., a buffering role of the circuit pattern for electrical connection is required. The buffering role may mean having a size between a width or spacing of the circuit pattern of the semiconductor package and a width or spacing of the circuit pattern of the semiconductor device, and the redistribution layer may include a function of performing the buffering role.

In an embodiment, the connection member 1210 may be an inorganic bridge. For example, the inorganic bridge may be a silicon bridge. That is, the connection member 1210 may include a silicon circuit board and a redistribution layer disposed on the silicon circuit board.

In another embodiment, the connection member 1210 may be an organic bridge. For example, the connection member 1210 may include an organic material. For example, the connection member 1210 may include an organic circuit board including an organic material instead of the silicon circuit board.

The connection member 1210 may be embedded in the second circuit board 1200, but is not limited thereto. For example, the connection member 1210 may be disposed on the second circuit board 1200 to have a protruding structure.

Also, the second circuit board 1200 may include a cavity, and the connection member 1210 may be disposed in the cavity of the second circuit board 1200.

The connection member 1210 may horizontally connect a plurality of semiconductor devices disposed on the second circuit board 1200.

Referring to FIG. 1c, the semiconductor package according to the third embodiment may include a second circuit board 1200 and a semiconductor device 1300. In this case, the semiconductor package of the third embodiment may have a structure in which the first circuit board 1100 is removed compared to the semiconductor package of the second embodiment.

That is, the second circuit board 1200 of the third embodiment may function as a package substrate while performing an interposer function.

The first connection part 1410 disposed on the lower surface of the second circuit board 1200 may couple the second circuit board 1200 to the main board of the electronic device.

Referring to FIG. 1d, the semiconductor package according to the fourth embodiment may include a first circuit board 1100 and a semiconductor device 1300.

In this case, the semiconductor package of the fourth embodiment may have a structure in which the second circuit board 1200 is omitted compared to the semiconductor package of the second embodiment.

That is, the first circuit board 1100 of the fourth embodiment can function as a package circuit board while also performing the function of connecting the semiconductor device 1300 and a main board. To this end, the first circuit board 1100 may include a connection member 1110 for connecting the plurality of semiconductor devices. The connection member 1110 may be an inorganic bridge or an organic material bridge connecting a plurality of semiconductor devices.

Referring to FIG. 1e, the semiconductor package of the fifth embodiment further may include a third semiconductor device 1330 compared to the semiconductor package of the fourth embodiment.

To this end, a fourth connection part 1440 may be disposed on the lower surface of the first circuit board 1100.

In addition, a third semiconductor device 1330 may be disposed on the fourth connection part 1400. That is, the semiconductor package of the fifth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 1c.

Referring to FIG. 1f, the semiconductor package according to the sixth embodiment may include a first circuit board 1100. A first semiconductor device 1310 may be disposed on the first circuit board 1100. To this end, a first connection part 1410 may be disposed between the first circuit board 1100 and the first semiconductor device 1310.

In addition, the first circuit board 1100 may include a conductive coupling portion 1450. The conductive coupling portion 1450 may further protrude from the first circuit board 1100 toward the second semiconductor device 1320. The conductive coupling portion 1450 may be referred to as a bump or, alternatively, may also be referred to as a post. The conductive coupling portion 1450 may be disposed to have a protruding structure on an electrode disposed on an uppermost side of the first circuit board 1100.

A second semiconductor device 1320 may be disposed on the conductive coupling portion 1450. In this case, the second semiconductor device 1320 may be connected to the first circuit board 1100 through the conductive coupling portion 1450. In addition, a second connection part 1420 may be disposed on the first semiconductor device 1310 and the second semiconductor device 1320.

Accordingly, the second semiconductor device 1320 may be electrically connected to the first semiconductor device 1310 through the second connection part 1420.

That is, the second semiconductor device 1320 is connected to the first circuit board 1100 through the conductive coupling portion 1450, and can also be connected to the first semiconductor device 1310 through the second connection part 1420.

At this time, the second semiconductor device 1320 can receive a power signal and/or electric power through the conductive coupling portion 1450. In addition, the second semiconductor device 1320 can exchange communication signals with the first semiconductor device 1310 through the second connection part 1420.

The semiconductor package according to the sixth embodiment may provide a power signal and/or electric power to the second semiconductor device 1320 through the conductive coupling portion 1450, thereby providing sufficient power for driving the second semiconductor device 1320 or enabling smooth control of a power operation.

Accordingly, the embodiment may improve the driving characteristics of the second semiconductor device 1320. That is, the embodiment may solve a problem of insufficient power provided to the second semiconductor device 1320. Furthermore, in the embodiment, at least one of a power signal, an electric power, and a communication signal of the second semiconductor device 1320 may be provided through different paths through the conductive coupling portion 1450 and the second connection part 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure in which a plurality of package circuit boards are stacked and may be disposed on the first circuit board 1100. For example, the second semiconductor device 1320 may be a memory package including a memory chip. In addition, the memory package may be coupled on the conductive coupling portion 1450. In this case, the memory package may not be connected to the first semiconductor device 1310.

Meanwhile, the semiconductor package in the sixth embodiment may include a molding member 1460. The molding member 1460 may be disposed between the first circuit board 1100 and the second semiconductor device 1320. For example, the molding member 1460 may mold the first connection part 1410, the second connection part 1420, the first semiconductor device 1310, and the conductive coupling portion 1450.

Referring to FIG. 1g, the semiconductor package according to the seventh embodiment may include a first circuit board 1100, a first connection part 1410, a first connection part 1410, a semiconductor device 1300, and a third connection part 1430.

In this case, the semiconductor package of the seventh embodiment may differ from the semiconductor package of the fourth embodiment in that the first circuit board 1100 includes a plurality of circuit board layers while the connection member 1110 is omitted.

The first circuit board 1100 may include a plurality of circuit board layers. For example, the first circuit board 1100 may include a first circuit board layer 1100A corresponding to a package substrate and a second circuit board layer 1100B corresponding to the connection member.

In other words, the semiconductor package of the seventh embodiment may include a first circuit board layer 1100A and a second circuit board layer 1100B in which the first circuit board (package circuit board, 1100) and the second circuit board (interposer, 1200) disclosed in FIG. 1a are integrally formed. A material of the insulating layer of the second circuit board layer 1100B may be different from a material of an insulating layer of the first circuit board layer 1100A. For example, the material of an insulating layer of the second circuit board layer 1100B may include a photocurable material. For example, the second circuit board layer 1100B may be a photo imageable dielectric (PID). In addition, since the second circuit board layer 1100B includes a photocurable material, it is possible to miniaturize the electrode. Accordingly, in the seventh embodiment, the second circuit board layer 1100B may be formed by sequentially stacking an insulating layer of a photo-curable material on the first circuit board layer 1100A and forming a miniaturized electrode on the insulating layer of the photo-curable material. Accordingly, the second circuit board layer 1100B may include a redistribution layer function including a micro-electrode and may include a function of horizontally connecting a plurality of semiconductor devices 1310 and 1320.

Hereinafter, a circuit board provided in a semiconductor package of an embodiment will be described. In one embodiment, the circuit board described below may refer to the first circuit board 1100 illustrated in FIGS. 1a to 1g. In another embodiment, the circuit board described below may refer to the second circuit board 1200 illustrated in FIGS. 1a to 1g.

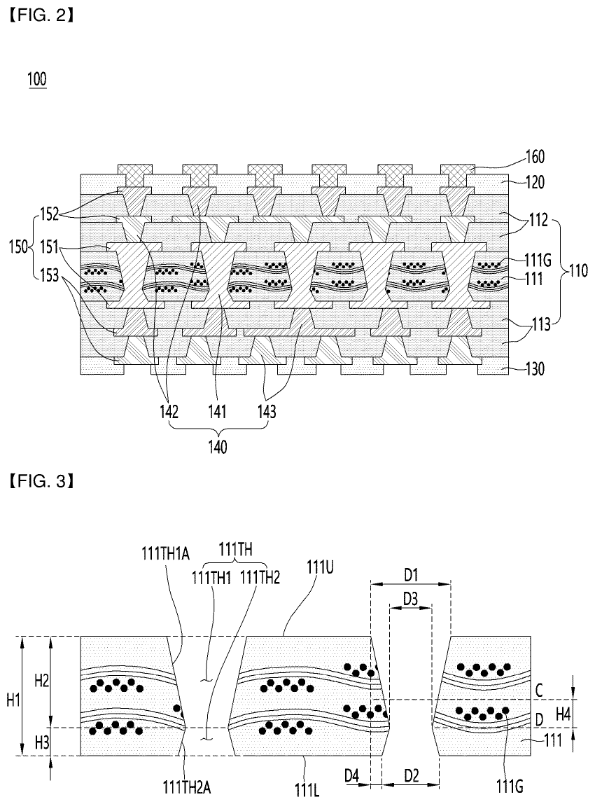

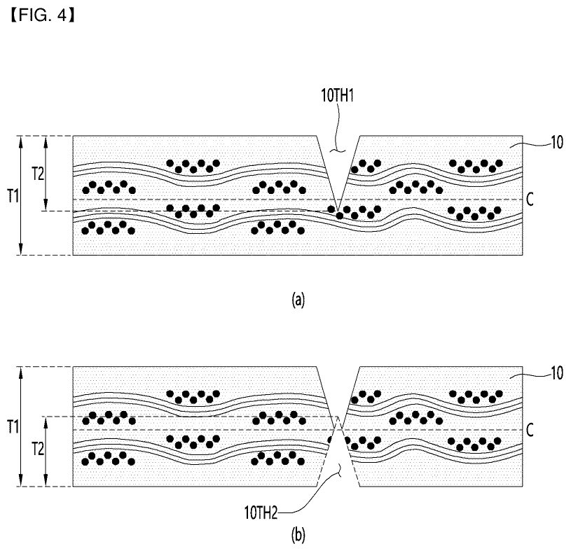

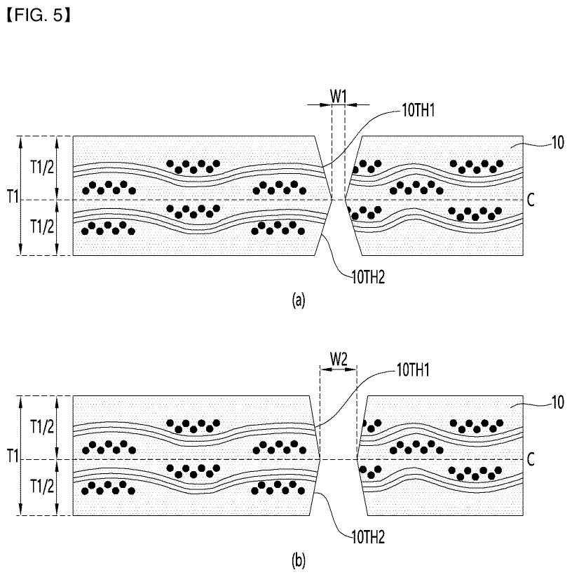

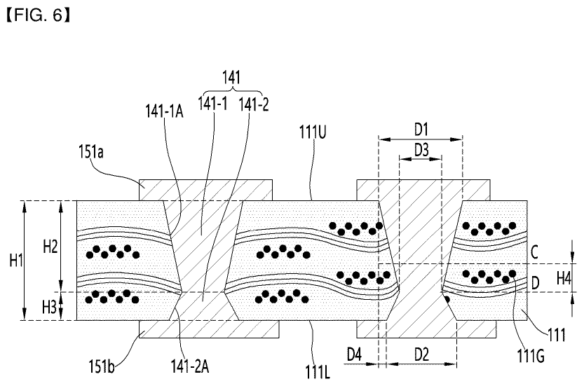

FIG. 2 is a cross-sectional view illustrating a circuit board according to a first embodiment, FIG. 3 is a cross-sectional view illustrating a through hole provided in a first insulating layer of FIG. 2, FIG. 4 is a cross-sectional view illustrating a process for forming a through hole in a core insulating layer according to a comparative example, FIG. 5 is a cross-sectional view illustrating a through hole provided in a core insulating layer according to a comparative example, and FIG. 6 is a cross-sectional view illustrating a through electrode provided in the first insulating layer of FIG. 2.

Referring to FIG. 2, the circuit board includes an insulating layer 110, a protective layer 120, and 130, and electrode parts 140, 150, and 160. In this case, the circuit board of FIG. 2 of one embodiment may refer to the first circuit board 1100 illustrated in FIGS. 1a to 1g. In addition, the circuit board of FIG. 2 of another embodiment may refer to the second circuit board 1200 illustrated in FIGS. 1a to 1g.

The insulating layer 110 may include an organic material that does not include a reinforcement member, which has excellent processability, enables slimming of the circuit, and enables miniaturization of the electrode part provided in the circuit board 100. For example, the insulating layer 110 can utilize ABF (Ajinomoto Build-up Film), a product released by Ajinomoto, as an example. FR-4, BT (Bismaleimide Triazine), and PID (Photo Image-able Dielectric Resin) can also be used.

The insulating layer 110 can be formed by stacking a plurality of layers.

The insulating layer 110 can be formed by sequentially stacking a first insulating layer 111, a second insulating layer 112, and a third insulating layer 113 along a vertical direction.

The first insulating layer 111 may mean a layer disposed at a center in a stacked structure of the insulating layer in a vertical direction, the second insulating layer 112 may mean a layer disposed on the first insulating layer 111, and the third insulating layer 113 may mean a layer disposed under the first insulating layer 111.

In addition, at least one of the second insulating layer 112 and the third insulating layer 113 may be provided as a plurality of layers. For example, as illustrated in FIG. 2, each of the second insulating layer 112 and the third insulating layer 113 may have a two-layer structure along the vertical direction, but is not limited thereto. Each of the second insulating layer 112 and the third insulating layer 113 may be provided as a single layer, or may have a number of layers greater than two.

In addition, as illustrated in FIG. 2, the insulating layer 110 including the first insulating layer 111, the second insulating layer 112, and the third insulating layer 113 may have a five-layer structure along the vertical direction, but is not limited thereto. That is, the insulating layer 110 may have a number of layers less than five along the vertical direction, or may have a number of layers greater than five.

The first insulating layer 111 may include an insulating material different from the second insulating layer 112 and the third insulating layer 113. Preferably, the circuit board 100 of the embodiment may be a core board including a first insulating layer 111 corresponding to a core insulating layer. Here, the core insulating layer refers to a thickest insulating layer among the plurality of layers of the insulating layer 110. That is, the first insulating layer 111 corresponding to the core insulating layer may be thicker than each of the second insulating layer 112 and the third insulating layer 113.

The first insulating layer 111 may be a prepreg (PPG) having a reinforcement member 111G, and may refer to an insulating layer including a reinforcement member 111G such as a glass core primer (GCP) or glass fiber. At least a portion of a reinforcement member 111G provided in the first insulating layer 111 may be exposed through a through hole penetrating the first insulating layer 111. For example, at least a portion of the reinforcement member 111G may protrude through toward a through hole of the first insulating layer 111. In addition, a portion of the reinforcement member 111G protruding toward the through hole may be embedded within a first through electrode 141 provided in the through hole of the first insulating layer 111. Through this, the embodiment can further improve the adhesion between a first through electrode 141 and the first insulating layer 111. For example, the reinforcement member 111G protruding toward the through hole can serve as an anchor function that improves the bonding strength between the first insulating layer 111 and the first through electrode 141, thereby improving the physical reliability and/or electrical reliability of the circuit board and the semiconductor package.

At this time, since the core insulating layer is thicker and harder than other insulating layers during a process, the core insulating layer can prevent the circuit board 100 from warping during the process or prevent warping that occurs when using a product to which a semiconductor package is applied.

In particular, as the number of semiconductor devices and/or semiconductor chiplets disposed on the circuit board 100 increases, the area and/or thickness of the circuit board 100 increases, and accordingly, the circuit board 100 has a problem of warping more significantly. Therefore, the circuit board 100 of the embodiment may include a first insulating layer 111 corresponding to the core insulating layer. Through this, the embodiment can prevent the circuit board 100 from warping significantly in a specific direction during a process of manufacturing process the circuit board 100, and further, can prevent the circuit board 100 from warping significantly in a specific direction even after the manufacturing of the circuit board 100 is completed. Through this, the embodiment can improve the physical reliability of the circuit board 100. Furthermore, the embodiment can ensure that the electrode parts 140, 150, and 160 are disposed at accurate positions in the circuit board 100, thereby improving the electrical reliability of the circuit board 100. In addition, the embodiment may allow the semiconductor device to be stably disposed on the circuit board 100, and furthermore, allow the semiconductor device to operate stably.

Referring to FIG. 3, the first insulating layer 111 has a thickness greater than thicknesses of the second insulating layer 112 and the third insulating layer 113. The thickness H1 of the first insulating layer 111 can satisfy a range of 100 μm to 700 μm. Preferably, the thickness H1 of the first insulating layer 111 can satisfy a range of 120 μm to 680 μm. More preferably, the thickness H1 of the first insulating layer 111 may satisfy a range of 150 μm to 650 μm. Here, the thickness H1 of the first insulating layer 111 may refer to a vertical distance between an upper surface 111U and a lower surface 111L of the first insulating layer 111.

If the thickness H1 of the first insulating layer 111 is less than 100 μm, an effect of increasing the rigidity of the circuit board 100 by the first insulating layer 111 may be insignificant, and thus, a problem of the circuit board 100 being significantly warped in a specific direction may occur during the manufacturing process of the circuit board 100 or after the manufacturing of the circuit board 100 is completed. If the thickness H1 of the first insulating layer 111 exceeds 700 μm, it may be difficult to thin the circuit board 100 and the semiconductor package. In addition, if the thickness H1 of the first insulating layer 111 exceeds 700 μm, signal transmission loss, etc. may increase due to the reinforcement member 111G provided in the first insulating layer 111, which may deteriorate the electrical reliability of the circuit board 100 and the semiconductor package.

In addition, each of the second insulating layer 112 and the third insulating layer 113 may be provided with a thickness smaller than the thickness H1 of the first insulating layer 111 at the upper and lower portions of the first insulating layer. For example, the second insulating layer 112 refers to an upper insulating layer disposed on the core insulating layer, and the third insulating layer 113 refers to a lower insulating layer disposed under below the core insulating layer.

Each of the first insulating layer 111, the second insulating layer 112, and the third insulating layer 113 may include a through hole. The through hole may penetrate upper and lower surfaces of the first insulating layer 111, the second insulating layer 112, and the third insulating layer 113, respectively.

For example, the first insulating layer 111 may include a through hole 111TH. The through hole 111TH may penetrate between the upper surface 111U and the lower surface 111L of the first insulating layer 111 in a vertical direction. In addition, the second insulating layer 112 and the third insulating layer 113 may each include a through hole. At this time, a part of the electrode part 140, 150, and 160 may be embedded in the second insulating layer 112 and the third insulating layer 113, and accordingly, the through hole of the second insulating layer 112 and the third insulating layer 113 may overlap with the electrode part 140, 150, and 160 embedded therein in the vertical direction.

A vertical cross-sectional shape of the through hole 111TH provided in the first insulating layer 111 may differ from vertical cross-sectional shapes of the through holes provided in each of the second insulating layer 112 and the third insulating layer 113.

For example, the first insulating layer 111 has a thickness H1 greater than a certain level and includes a reinforcement member 111G therein. Therefore, it may be difficult to form a through hole 111TH penetrating the first insulating layer 111 from either an upper or lower side. Accordingly, the through hole 111TH provided in the first insulating layer 111 may have a vertical cross-sectional shape with inner walls having multiple different slopes. For example, the vertical cross-sectional shape of the through hole 111TH provided in the first insulating layer 111 may have an hourglass shape.

The through holes provided in each of the second insulating layer 112 and the third insulating layer 113 may have a vertical cross-sectional shape having an inner wall of a single slope. For example, the vertical cross-sections of the through holes provided in each of the second insulating layer 112 and the third insulating layer 113 may have a trapezoidal shape. At this time, the through hole provided in the second insulating layer 112 may have a slope in which the width gradually decreases from the upper surface of the second insulating layer 112 toward the lower surface of the second insulating layer 112. In addition, the through hole provided in the third insulating layer 113 may have a slope in which the width gradually decreases from the lower surface of the third insulating layer 113 toward the upper surface of the third insulating layer 113. For example, the through hole provided in the second insulating layer 112 may have a symmetrical shape to the through hole provided in the third insulating layer 113 with respect to the first insulating layer 111, but is not limited thereto.

The through hole 111TH provided in the first insulating layer 111 will be described in detail as follows.

The through hole 111TH provided in the first insulating layer 111 may include a first hole part 111TH1 adjacent to the upper surface 111U of the first insulating layer 111 and having a first slope 111TH1A whose width gradually decreases from the upper surface 111U of the first insulating layer 111 toward the lower surface 111L of the first insulating layer 111. In addition, the through hole 111TH provided in the first insulating layer 111 may include a second hole part 111TH2 adjacent to the lower surface 111L of the first insulating layer 111 and having a second slope 111TH2A whose width gradually decreases from the lower surface 111L of the first insulating layer 111 toward the upper surface 111U of the first insulating layer 111. At this time, the first slope 111TH1A and the second slope 111TH2A may have slopes that are inclined in different directions along the vertical direction from the upper surface 111U of the first insulating layer 111 toward the lower surface 111L. At this time, each of a slope angle of the first slope 111TH1A and a slope angle of the second slope 111TH2A may not be constant along a thickness direction. For example, each of the first slope 111TH1A and the second slope 111TH2A may have a curve. In this case, the slope angle of the first slope 111TH1A may mean a slope angle with respect to an imaginary straight line connecting upper and lower ends of the first slope 111TH1A. In addition, the slope angle of the second slope 111TH2A may mean a slope angle with respect to an imaginary straight line between upper and lower ends of the second slope 111TH2A.

In an embodiment, the through hole 111TH of the first insulating layer 111 includes a first hole part 111TH1 of a first slope 111TH1A and a second hole part 111TH2 of a second slope 111TH2A different from the first slope 111TH1A, thereby improving the processability in the process of filling the through hole 111TH with a conductive material and enhancing the product yield.

For example, the first insulating layer 111 may be provided with a through hole having a constant slope and a width that does not change from an upper surface toward a lower surface. That is, the through hole in the first insulating layer 111 may be formed using a CNC drill, and thus the width of the through hole may be constant from an upper portion to a lower portion. At this time, when the plating process is performed to fill the inside of the through hole with a conductive material, a plating speed at an entrance portion of the through hole adjacent to the upper and/or lower surface of the insulating layer is faster than a plating speed at an inner portion of the through hole that is farther from the upper and/or lower surface of the insulating layer than the entrance portion. Therefore, when widths of the upper and lower surfaces of the through hole are the same, it may be difficult to densely fill the inside of the through hole with a conductive material, and voids may be formed inside the through hole. Therefore, when the widths of the upper and lower surfaces of the through hole are the same, a portion of the through hole may be filled with an insulating member such as hole plugging ink. At this time, the insulating layer having the reinforcement member and the insulating member may have different coefficients of thermal expansion, which may cause reliability problems such as cracks occurring in the through electrode penetrating the insulating layer due to stress acting according to the heat cycle. In addition, when a portion of the inside of a through hole is filled with an insulating member, a process of plating a metal material corresponding to the through electrode along an inner wall of the through hole and a process of filling the insulating member must be performed separately, which complicates the manufacturing process and may deteriorate product yield.

In contrast, the through hole 111TH provided in the first insulating layer 111 includes a first slope 111TH1A and a second slope 111TH2A, whose width varies along the vertical direction between the upper surface 111U and the lower surface 111L of the first insulating layer 111, and inclined in different directions. Therefore, the embodiment can entirely plate the through hole 111TH of the first insulating layer 111 with a conductive material, thereby simplifying the manufacturing process and improving product yield. Furthermore, since the through hole 111TH of the first insulating layer 111 is entirely plated with a conductive material, the rigidity of the first insulating layer 111, the rigidity of the circuit board 100, and the rigidity of the semiconductor package can be improved, thereby preventing the circuit board 100 and the semiconductor package from being significantly warped in a specific direction.

At this time, the thickness H1 of the first insulating layer 111 is increasing, and thus, even if the through hole 111TH of the first insulating layer 111 only includes a first slope 111TH1A and a second slope 111TH2A, it may be difficult to densely fill the inside of the through hole 111TH with a conductive material.

Therefore, in the embodiment, a vertical length H2 of the first slope 111TH1A and a vertical length H3 of the second slope 111TH2A are different from each other. Through this, the embodiment improves the flatness of the upper and lower surfaces of the electrode part penetrating the first insulating layer 111 while eliminating void regions in the through hole 111TH where a portion of the through hole is not filled with conductive material.

For example, a through hole provided in the core insulating layer of the comparative example includes first and second slopes inclined in different directions, but vertical lengths of the first slope and the second slope are identical. Here, “identical” means that the vertical length of the first slope satisfies a range of 80% to 120% of the vertical length of the second slope. As the thickness of the core insulating layer increases, the vertical lengths of the first slope and the second slope increase. Accordingly, a horizontal width of the through hole in a region where the first and second slopes meet may be either too small or excessively expanded, depending on a distribution of ends of a Gaussian beam during a laser process.

Referring to FIG. 4, the comparative example performs a process of forming a hole part penetrating a portion of the core insulating layer 10 at each of the upper and lower sides of the core insulating layer 10.

For example, referring to (a) of FIG. 4, the comparative example provides a first Gaussian beam from an upper side of the core insulating layer 10 toward the upper surface of the core insulating layer 10 to form a first hole part 10TH1 penetrating a portion of the core insulating layer 10 on the upper surface of the core insulating layer 10. At this time, the first Gaussian beam has an intensity capable of processing a depth T2 of approximately 60% of the thickness T1 in the vertical direction between the upper and lower surfaces of the core insulating layer 10.

In addition, referring to (b) of FIG. 4, the comparative example provides a second Gaussian beam from a lower side of the core insulating layer 10 toward the lower surface of the core insulating layer 10 to form a second hole part 10TH2 penetrating a portion of the core insulating layer on the lower surface of the core insulating layer 10. At this time, the second Gaussian beam has an intensity capable of processing a depth T2 of approximately 60% of the thickness T1 in the vertical direction between the upper and lower surfaces of the core insulating layer 10, corresponding to the first Gaussian beam.

Referring to FIG. 5, the comparative example sequentially performs the processes of (a) and (b) of FIG. 4, and accordingly, a through hole including a first hole part TH1 and a second hole part TH2 inclined in different directions may be formed in the core insulating layer 10.

At this time, a vertical length (T1/2) of the first slope of the first hole part TH1 of the comparative example is substantially the same as a vertical length (T1/2) of the second slope of the second hole part TH2. The vertical length (T1/2) of the first slope of the first hole part TH1 of the comparative example may be half the thickness T1 of the core insulating layer 10, and the vertical length (T1/2) of the second slope of the second hole part TH2 may also be half the thickness of the core insulating layer 10. For example, the vertical length (T1/2) of the first slope of the first hole part TH1 of the comparative example satisfies a range of 80% to 120% of the vertical length (T1/2) of the second slope of the second hole part TH2.

Accordingly, in the comparative example, a width of a center portion of the through hole provided in the core insulating layer 10 may vary significantly depending on the distribution of the first and second Gaussian beams. Therefore, if the width of the center portion of the through hole is too small, the comparative example may include a void where a portion of the inside of the through hole is not filled with conductive material. Conversely, if the width of the center portion of the through hole is too large, the comparative example may include a concave portion on upper and/or lower surfaces of the electrode part disposed in the through hole.

For example, referring to (a) of FIG. 5, the first Gaussian beam has a distribution in which the intensity decreases from the upper surface toward the lower surface of the core insulating layer 10, and the second Gaussian beam has a distribution in which the intensity decreases from the lower surface toward the upper surface of the core insulating layer 10. Accordingly, in the comparative example, a Gaussian beam with a lowest intensity may be provided at a center horizontal line C of the core insulating layer 10 where the first and second Gaussian beams meet. Therefore, in the comparative example, a width W1 of the through hole provided in the core insulating layer 10 at the center horizontal line C may be excessively smaller than the upper width and/or lower width of the through hole. In this case, in the comparative example, a void may be provided in which a conductive material is not filled due to the excessively small width W1 of the through hole at the center horizontal line C.

Furthermore, referring to (b) of FIG. 5, residual energy may exist at each end of the first and second Gaussian beams, and the residual energy may cause the width of the center of the through hole to expand. As a result, a width W2 of the through hole at the center horizontal line C in the comparative example may be excessively expanded. In this case, since the width W2 of the through hole at the center horizontal line C is expanded too greatly, the process capability in a plating process using copper ions, suppressors, and accelerators may be deteriorated, and thus, concave dimples may be formed on the upper and lower surfaces of the electrode part.

Accordingly, the embodiment allows the vertical length H2 of the first slope 111TH1A of the through hole 111TH provided in the first insulating layer 111 to be different from the vertical length H3 of the second slope 111TH2A, and further allows the plating process capability in the plating process of filling the through hole 111TH with a conductive material to be improved by controlling the ratio of the vertical length H2 of the first slope 111TH1A and the vertical length H3 of the second slope 111TH2A.

For example, the vertical length H2 of the first slope 111TH1A of the through hole 111TH provided in the first insulating layer 111 may be greater than the vertical length H3 of the second slope 111TH2A. At this time, the vertical length H2 of the first slope 111TH1A may mean a vertical distance from the upper surface 111U of the first insulating layer 111 to a lowermost end of the first slope 111TH1A or an uppermost end of the second slope 111TH2A. In addition, the vertical length H3 of the second slope 111TH2A may mean a vertical distance from the lower surface 111L of the first insulating layer 111 to an uppermost end of the second slope 111TH2A or a lowermost end of the first slope 111TH1A.

The vertical length H2 of the first slope 111TH1A can satisfy a range of 70% to 80% of the thickness H1 of the first insulating layer 111. In addition, the vertical length H3 of the second slope 111TH2A can satisfy a range of 20% to 30% of the thickness H1 of the first insulating layer 111. For example, a ratio of the vertical length H2 of the first slope 111TH1A to the vertical length H3 of the second slope 111TH2A can satisfy a range of 7:3 to 8:2.

If the ratio of the vertical length H2 of the first slope 111TH1A to the vertical length H3 of the second slope 111TH2A is less than 7:3, the ratio of the vertical length H2 of the first slope 111TH1A to the vertical length H3 of the second slope 111TH2A may be close to 5:5, and accordingly, a void may be provided in the process of plating the through hole 111TH with a conductive material, or a concave part may be provided on the upper surface and/or lower surface of the electrode part provided in the through hole 111TH. In addition, if the ratio of the vertical length H2 of the first slope 111TH1A to the vertical length H3 of the second slope 111TH2A is greater than 8:2, the vertical length H3 of the second slope 111TH2A of the second hole part 111TH2 may be too small, and accordingly, the through hole 111TH may not penetrate the upper surface 111U and the lower surface 111L of the first insulating layer 111, or the process time for forming the through hole 111TH may increase. As a result, the product yield may decrease.

At this time, although it is said that the vertical length H2 of the first slope 111TH1A is greater than the vertical length H3 of the second slope 111TH2A, these may have opposite meanings. For example, depending on a direction in which the first insulating layer 111 is viewed, the upper surface 111U and the lower surface 111L of the first insulating layer 111 may be referred to as opposite surfaces, and accordingly, the vertical length H2 of the first slope 111TH1A and the vertical length H3 of the second slope 111TH2A may have a range of 2:8 to 3:7.

The through hole 111TH provided in the first insulating layer 111 may have a first width D1 at an upper end of the first slope 111TH1A and a second width D2 at a lower end of the second slope 111TH2A. In addition, the through hole 111TH may have a third width D3 smaller than the first width D1 and the second width D2 in a region where the first slope 111TH1A and the second slope 111TH2A meet. In addition, the region where the first slope 111TH1A and the second slope 111TH2A meet may be positioned lower than a center horizontal line C of the first insulating layer 111. For example, the region where the first slope 111TH1A and the second slope 111TH2A meet may be positioned closer to the lower surface 111L than to the upper surface 111U of the first insulating layer 111.

In addition, the first width D1 at an upper end of the first slope 111TH1A of the through hole 111TH may refer to an upper width of the first hole part 111TH1 of the through hole 111TH, and the second width D2 at a lower end of the second slope 111TH2A of the through hole 111TH may refer to a lower width of the second hole part 111TH2 of the through hole 111TH.

At this time, the embodiment controls the difference between the first width D1 and the second width D2, thereby improving the processability in the process of filling the through hole 111TH with a conductive material and reducing the resistance of the first through electrode 141 provided in the through hole 111TH, thereby improving electrical characteristics.

For example, a difference value (D1−D2) between the first width D1 and the second width D2 of the embodiment is smaller than a difference value (H2−H3) between the vertical length H2 of the first slope 111TH1A of the through hole 111TH and the vertical length H3 of the second slope 111TH2A. If the difference value (D1−D2) between the first width D1 and the second width D2 of the embodiment is greater than the difference value (H2−H3) between the vertical length H2 of the first slope 111TH1A of the through hole 111TH and the second slope 111TH2A, a difference may occur between a plating amount in the first hole part 111TH1 and a plating amount in the second hole part 111TH1 in the process of plating the through hole 111TH, and as a result, the flatness of the upper surface and/or lower surface of the electrode part provided in the through hole 111TH may deteriorate. In addition, if the flatness of the electrode part provided in the through hole 111TH deteriorates, the flatness of the electrode part provided on the upper and/or lower surface thereof may also deteriorate, and as a result, the semiconductor device may not be stably disposed on the circuit board 100. In addition, if the difference (D1−D2) between the first width D1 and the second width D2 of the embodiment is greater than the difference (H2−H3) between the vertical length H2 of the first slope 111TH1A and the second slope 111TH2A of the through hole 111TH, the resistance of the first through electrode 141 caused by the difference between the first width D1 and the second width D2 may increase, thereby deteriorating the electrical characteristics of the circuit board 100.

For example, the resistance of the electrode part is divided into resistance due to the width and/or area of the electrode part and resistance according to the thickness of the electrode part. In this case, the thickness of the electrode part corresponds to the thickness H1 of the first insulating layer 111 and may be fixed. However, the resistance due to the width and/or area of the electrode part decreases as the difference in the width of the upper and lower surfaces of the first through electrode 141 approaches 0, and may be reduced by half when the widths of the upper and lower surfaces of the first through electrode 141 are the same. That is, the surface resistance due to the width and/or area of the electrode part may be reduced by half when the widths of the upper and lower surfaces of the electrode part are the same, and may be increased as the difference in the width of the upper and lower surfaces of the electrode part increases.

Therefore, the embodiment allows the difference value (D1−D2) between the first width D1 and the second width D2 to be smaller than the difference value (H2−H3) between the vertical length H2 of the first slope 111TH1A of the through hole 111TH and the second slope 111TH2A, thereby improving the processability in the process of plating the through hole 111TH, thereby improving the product yield, and reducing the resistance of the first through electrode 141, thereby improving the electrical characteristics.

In addition, in the embodiment, a difference value ((D1−D3)−(D2−D3)) between the difference value (D1−D3) between the first width D1 and the third width D3 of the through hole 111TH and the difference value (D2−D3) between the second width D2 and the third width D3 may be smaller than the difference value (H2−H3) between the vertical length H2 of the first slope 111TH1A and the second slope 111TH2A. In the embodiment, if the difference value ((D1−D3)−(D2−D3)) between the difference value (D1−D3) between the first width D1 and the third width D3 of the through hole 111TH and the difference value (D2−D3) between the second width D2 and the third width D3 are greater than the difference value (H2−H3) between the vertical length H2 of the first slope 111TH1A and the vertical length H3 the second slope 111TH2A, the flatness of the upper surface and/or lower surface of the electrode part provided in the through hole 111TH may be reduced depending on the plating deviation of the electrode part provided in the first hole part 111TH1 and the second hole part 111TH2. In addition, if the difference value ((D1−D3)−(D2−D3)) between the difference value (D1−D3) between the first width D1 and the third width D3 of the through hole 111TH and the difference value (D2−D3) between the second width D2 and the third width D3 is greater than the difference value (H2−H3) between the vertical length H2 of the first slope 111TH1A and the vertical length H3 of the second slope 111TH2A, the resistance of the first through electrode 141 may increase, and thus the electrical characteristics of the circuit board 100 may deteriorate.

In addition, the difference value (D1−D2) between the first width D1 and the second width D2 of the through hole 111TH may be smaller than a vertical length H4 from a center horizontal line C of the first insulating layer 111 to a region (D) where the first slope 111TH1A and the second slope 111TH2A meet. Furthermore, a horizontal length D4 between an upper end of the first slope 111TH1A on one side of the through hole 111TH and a lower end of the second slope 111TH2A on one side of the through hole 111TH may be smaller than the vertical length H4 from the center horizontal line C of the first insulating layer 111 to the region (D) where the first slope 111TH1A and the second slope 111TH2A meet. For example, the horizontal length D4 may be half the difference value (D1−D2) between the first width D1 and the second width D2 of the through hole 111TH. If the horizontal length D4 is greater than the vertical length H4, the flatness of the upper and/or lower surfaces of the electrode part provided in the through hole 111TH may deteriorate due to plating deviations in the first hole part 111TH1 and the second hole part 111TH2 of the electrode part, or the resistance of the first through electrode 141 may increase, thereby deteriorating the electrical characteristics of the circuit board 100.

The circuit board 100 includes electrode parts 140, 150, and 160. The electrode parts 140, 150, and 160 may be classified into a through electrode 140, a wiring electrode 150, and a bump electrode 160 depending on their positions.

The through electrode 140 may be provided to penetrate at least one of the first insulating layer 111, the second insulating layer 112, and the third insulating layer 113 of the insulating layer 110 in the vertical direction and may be referred to as a via electrode.

The wiring electrode 150 may be provided on upper and/or lower surfaces of each of the first insulating layer 111, the second insulating layer 112, and the third insulating layer 113 and may include traces and/or pads.

The traces function to transmit signals and/or power to the semiconductor device and may be referred to as circuit patterns. The pad functions as a connection portion for electrically connecting the semiconductor device and traces, or connecting traces disposed on each insulating layer. If a width of the trace is sufficiently large to directly connect the semiconductor device to the traces, the pads may be unnecessary. However, if the width of the trace is excessively large, there is a risk of increased impedance, and there is a problem in that the degree of integration of traces cannot be increased in a limited area of the circuit board. Therefore, pads generally function as electrical conduction along with traces, but are equipped to have a wider width than traces to place them to have more functionality to contact through electrodes or semiconductor devices.

The through electrode 140 is provided to penetrate at least one layer of the insulating layer 110 and be connected to the pad, and may be referred to as a via electrode. The through electrode 140 also has the same electrical conductivity function as the pad and/or trace, but is configured to be disposed along the vertical direction, and may have a side surface different from a side surface of the pad and/or trace of the wiring electrode 150 depending on a process method. According to one embodiment, the pad connected to the through electrode may be formed integrally. In this case, the upper surface of the through electrode may be understood as a same surface as a lower surface of the pad disposed on the through electrode and connected to the through electrode, and a lower surface of the through electrode may be understood as an upper surface of a pad disposed below the through electrode and connected to the through electrode. In addition, the upper and lower surfaces of the pad according to the embodiment may not necessarily mean only a flat surface, and specifically, may be interpreted in various ways according to the understanding of those skilled in the art.

The through electrode 140 may include a first through electrode 141 penetrating the first insulating layer 111, a second through electrode 142 penetrating the second insulating layer 112, and a third through electrode 143 penetrating the third insulating layer 113. The first through electrode 141, the second through electrode 142, and the third through electrode 143 may be provided along a vertical direction in the circuit board 100. In addition, the wiring electrode 150 may include a first wiring electrode 151 disposed on the upper surface and/or lower surface of the first insulating layer 111, a second wiring electrode 152 disposed on the upper surface of the second insulating layer 112, and a third wiring electrode 153 disposed on the lower surface of the third insulating layer 113.

The first through electrode 141 may include a plurality of slopes, and the second through electrode 142 and the third through electrode 143 may include a single slope.

For example, the first through electrode 141 may be disposed in a through hole 111TH provided in the first insulating layer 111, and thus may include slopes corresponding to the first slope 111TH1A and the second slope 111TH2A of the through hole 111TH. Furthermore, the second through electrode 142 may be disposed on the first through electrode 141 and include a single slope inclined in a same direction as the first slope 111TH1A. Furthermore, the third through electrode 143 may be disposed below the first through electrode 141 and include a single slope inclined in a same direction as the second slope 111TH2A.

The first through electrode 141 will be described in detail as follows. At this time, the first through electrode 141 is provided in a through hole 111TH provided in the first insulating layer 111, and thus may have a structure corresponding to the through hole 111TH described previously. Therefore, in the following description of the first through electrode 141, any description overlapping with the description of the through hole 111TH will be omitted.

The first through electrode 141 may include a first through part 141-1 adjacent to the upper surface 111U of the first insulating layer 111 and having a first slope 141-1A whose width gradually decreases from the upper surface 111U of the first insulating layer 111 toward the lower surface 111L of the first insulating layer 111. The first through part 141-1 may correspond to the first hole part 111TH1 of the through hole 111TH.

In addition, the first through electrode 141 may be provided with a second through part 141-2 adjacent to the lower surface 111L of the first insulating layer 111 and having a second slope 141-2A whose width gradually decreases from the lower surface 111L of the first insulating layer 111 toward the upper surface 111U of the first insulating layer 111. The second through part 141-2 may correspond to the second hole part 111TH2 of the through hole 111TH.

At this time, the first slope 141-1A and the second slope 141-2A may have slopes that are inclined in different directions along the vertical direction from the upper surface 111U of the first insulating layer 111 toward the lower surface 111L.

In the embodiment, the first through electrode 141 of the first insulating layer 111 includes a first through part 141-1 of a first slope 141-1A and a second through part 141-2 of a second slope 141-2A different from the first slope 141-1A, thereby improving the processability in the process of filling the first through electrode 141 with a conductive material and improving the product yield.

In addition, the vertical length H2 of the first slope 141-1A of the first through electrode 141 provided in the first insulating layer 111 and the vertical length H3 of the second slope 141-2A may be different from each other. In addition, the embodiment improves the plating process capability in the process of plating the first through electrode 141 by adjusting the ratio of the vertical length H2 of the first slope 141-1A and the vertical length H3 of the second slope 141-2A, and improves the electrical characteristics by reducing the resistance of the first through electrode 141.

For example, the vertical length H2 of the first slope 141-1A of the first through electrode 141 provided in the first insulating layer 111 may be greater than the vertical length H3 of the second slope 141-2A. In this case, the vertical length H2 of the first slope 141-1A may mean a vertical distance from the upper surface 111U of the first insulating layer 111 to a lowermost end of the first slope 141-1A or an uppermost end of the second slope 141-2A. In addition, the vertical length H2 of the first slope 141-1A may refer to a thickness of the first through part 141-1 of the first through electrode 141. In addition, the vertical length H3 of the second slope 141-2A may refer to a vertical distance from the lower surface 111L of the first insulating layer 111 to an uppermost end of the second slope 141-2A or a lowermost end of the first slope 141-1A. In addition, the vertical length H3 of the second slope 141-2A may refer to a thickness of the second through part 141-2 of the first through electrode 141.

The vertical length H2 of the first slope 141-1A of the first through part 141-1 may satisfy a range of 70% to 80% of the thickness H1 of the first through electrode 141. The thickness H1 of the first through electrode 141 may correspond to the thickness of the first insulating layer 111. In addition, the vertical length H3 of the second slope 141-2A of the second through part 141-2 may satisfy a range of 20% to 30% of the thickness H1 of the first through electrode 141.

For example, the ratio of the vertical length H2 of the first slope 141-1A of the first through part 141-1 to the vertical length H3 of the second slope 141-2A of the second through part 141-2 can satisfy a range of 7:3 to 8:2. If the ratio of the vertical length H2 of the first slope 141-1A to the vertical length H3 of the second slope 141-2A is less than 7:3, the ratio of the vertical length H2 of the first slope 141-1A and the vertical length H3 of the second slope 141-2A may be close to 5:5, and accordingly, a void may be provided in the process of plating the first through electrode 141, or a concave part may be provided on the upper surface of the first pad 151a disposed on the first through electrode 141 and/or on the lower surface of the second pad 151b disposed under the first through electrode 141. In addition, if the ratio of the vertical length H2 of the first slope 141-1A of the first through part 141-1 and the vertical length H3 of the second slope 141-2A of the second through part 141-2 is greater than 8:2, the vertical length H3 of the second slope 141-2A of the second through part 141-2 may be too small, and accordingly, the first through electrode 141 may not penetrate the upper surface 111U and the lower surface 111L of the first insulating layer 111, or the process time for forming the first through electrode 141 may increase. As a result, the product yield may be deterioated.

The first through electrode 141 may have a first width D1 at an upper end of the first slope 141-1A and a second width D2 at a lower end of the second slope 141-2A. In addition, the first through electrode 141 may have a third width D3 smaller than the first width D1 and the second width D2 at a region where the first slope 141-1A and the second slope 141-2A meet. The first width D1 may refer to a width of the upper surface of the first through part 141-1, the second width D2 may refer to a width of the lower surface of the second through part 141-2, and the third width D3 may refer to a width of an interface between the lower surface of the first through part 141-1 and the upper surface of the second through part 141-2.

In addition, the region where the first slope 141-1A and the second slope 141-2A meet may be positioned lower than a center horizontal line C of the first insulating layer 111 or the first through electrode 141. For example, the region where the first slope 141-1A and the second slope 141-2A meet may be positioned closer to the lower surface 111L of the first insulating layer 111 than to the upper surface 111U.

At this time, the embodiment controls the difference between the first width D1 and the second width D2, thereby improving the processability of the plating process of the first through electrode 141 and reducing the resistance of the first through electrode 141, thereby improving electrical characteristics.

For example, a difference value (D1−D2) between the first width D1 and the second width D2 of the embodiment is smaller than the difference value (H2−H3) between the vertical length H2 of the first slope 141-1A and the second slope 141-2A of the first through electrode 141. If the difference value (D1−D2) between the first width D1 and the second width D2 of the embodiment is greater than the difference value (H2−H3) between the vertical length H2 of the first slope 141-1A and the second slope 141-2A of the first through electrode 141, a difference may occur between the plating amount of the first through part 141-1 and the plating amount of the second through part 141-2 in the process of plating the first through electrode 141, and as a result, the flatness of the upper surface of the first pad 151a and/or the lower surface of the second pad 151b may be deterioated.

In addition, if the difference value (D1−D2) between the first width D1 and the second width D2 of the embodiment is greater than the difference value (H2−H3) between the vertical length H2 of the first slope 141-1A of the first through part 141-1 and the second slope 141-2A of the second through part 141-2, the resistance of the first through electrode 141 caused by the difference between the first width D1 and the second width D2 may increase, and thus the electrical characteristics of the circuit board 100 may deteriorate. Since the characteristics of the resistance of the first through electrode 141 have already been described above, a detailed description thereof will be omitted.

Therefore, the embodiment allows the difference value (D1−D2) between the first width D1 and the second width D2 to be smaller than the difference value (H2−H3) between the vertical length H2 of the first slope 141-1A of the first through part 141-1 and the vertical length H3 of the second slope 141-2A of the second through part 141-2, thereby improving the processability in the process of plating the first through electrode 141, thereby improving the product yield, and reducing the resistance of the first through electrode 141, thereby improving the electrical characteristics.

In addition, a difference value ((D1−D3)−(D2−D3)) between the difference value (D1−D3) between the first width D1 and the third width D3 of the first through electrode 141 and the difference value (D2−D3) between the second width D2 and the third width D3 of the embodiment may be smaller than the difference value (H2−H3) between the vertical length H2 of the first slope 141-1A and the second slope 141-2A. In the embodiment, if the difference value ((D1−D3)−(D2−D3)) between the difference value (D1−D3) between the first width D1 and the third width D3 of the first through electrode 141 and the difference value (D2−D3) between the second width D2 and the third width D3 of the embodiment is greater than the difference value (H2−H3) between the vertical length H2 of the first slope 141-1A and the second slope 141-2A, the flatness of the first pad 151a and/or the second pad 151b may be reduced depending on the plating deviation of the first through part 141-1 and the second through part 141-2

In addition, if the difference value ((D1−D3)−(D2−D3)) between the difference value (D1−D3) between the first width D1 and the third width D3 of the first through electrode 141 and the difference value (D2−D3) between the second width D2 and the third width D3 of the embodiment is greater than the difference value (H2−H3) between the vertical length H2 of the first slope 141-1A and the second slope 141-2A, the resistance of the first through electrode 141 may increase, and thus the electrical characteristics of the circuit board 100 may deteriorate.

In addition, the difference value (D1−D2) between the first width D1 and the second width D2 of the first through electrode 141 may be smaller than a vertical length H4 from a center horizontal line C to a region (D) where the first slope 141-1A and the second slope 141-2A meet. Furthermore, a horizontal length D4 between an upper end of the first slope 141-1A on one side of the first through electrode 141 and a lower end of the second slope 141-2A on one side of the first through electrode 141 may be smaller than a vertical length H4 from the center horizontal line C of the first insulating layer 111 to the region (D) where the first slope 141-1A and the second slope 141-2A meet. For example, the horizontal length D4 may be half the difference (D1−D2) between the first width D1 and the second width D2 of the first through electrode 141. If the horizontal length D4 is greater than the vertical length H4, the flatness of the first pad 151a and/or the second pad 151b may deteriorate, or the resistance of the first through electrode 141 may increase, thereby deteriorating the electrical characteristics of the circuit board 100.

In addition, the bump electrode 160 is disposed on the second wiring electrode 152. For example, the second wiring electrode 152 includes a pad part, and the bump electrode 160 is disposed on the pad part of the second wiring electrode 152.

In addition, the bump electrode 160 penetrates a first protective layer 120. In addition, the bump electrode 160 is provided to protrude on the first protective layer 120.

That is, the bump electrode 160 protrudes above the first protective layer 120 of the circuit board 100 to stably connect to the terminal of the semiconductor device using a connection part, such as solder. This allows the bump electrode 160 to maintain a certain distance between the connection part and the circuit board 100, thereby improving a positional alignment between the bump electrode 160 and the terminals of the semiconductor device.

That is, as the width of the terminals of the semiconductor device bonded to the circuit board and the pitch of the terminals become smaller, when the semiconductor device is mounted using a connection part such as a solder, the connection part may spread in the horizontal direction, which may cause a problem in which a plurality of connection part parts are connected to each other. For example, in the embodiment, thermal compression bonding may be performed to reduce the volume of the connection part. In this case, if the bump electrode 160 is not provided, it may be difficult to reduce the volume of the connection part. This may be because a height of an uppermost pad part where the connection part is disposed is positioned lower than the upper surface of the first protective layer 120, and thus the volume of the connection part increases by the difference in the height of the pad part and the first protective layer 120.

In particular, as the width and pitch of terminals of semiconductor devices are becoming smaller, and when a semiconductor device is mounted by applying a connection part such as solder without a bump electrode 160, a short circuit problem may occur in which two adjacent connection parts are connected to each other as a spacing between the connection parts becomes smaller. Therefore, the embodiment performs a semiconductor device mounting process by providing a bump electrode 160 and applying a connection part such as solder on the bump electrode 160. Preferably, the embodiment may perform thermal compression bonding using the bump electrode 160 protruding on an outermost side of the circuit board 100. Based on this, the embodiment can stably mount a semiconductor device on the circuit board, and thereby enable the semiconductor device to operate stably.

The through electrode 140, the wiring electrode 150, and the bump electrode 160 may be formed of at least one metal material selected from gold (Au), silver (Ag), platinum (Pt), titanium (Ti), tin (Sn), copper (Cu), and zinc (Zn). In addition, the through electrode 140, the wiring electrode 150, and the bump electrode 160 may be formed of a paste or solder paste containing at least one metal material selected from gold (Au), silver (Ag), platinum (Pt), titanium (Ti), tin (Sn), copper (Cu), and zinc (Zn) having excellent bonding strength. Preferably, the through electrode 140, the wiring electrode 150, and the bump electrode 160 may be formed of copper (Cu), which has high electrical conductivity and is relatively inexpensive.

The circuit board 100 includes a protective layer. That is, the circuit board 100 includes a first protective layer 120 disposed on the insulating layer 110. The first protective layer 120 is disposed on a second insulating layer 112 disposed on the uppermost side among the plurality of layers of the insulating layer 110. Furthermore, the circuit board 100 includes a second protective layer 130 disposed under the insulating layer 110. The second protective layer 130 is disposed under the second insulating layer 112 disposed on a lowermost side among the plurality of layers of the insulating layer 110.

The first protective layer 120 and the second protective layer 130 may be solder resist layers containing an organic polymer material. For example, the first protective layer 120 and the second protective layer 130 may include an epoxy acrylate resin. In detail, the first protective layer 120 and the second protective layer 130 may include resin, a curing agent, a photo initiator, a pigment, a solvent, a filler, an additive, an acrylic monomer, etc. However, the embodiment is not limited thereto, and the first protective layer 120 and the second protective layer 130 may of course be any one of a photo solder resist layer, a cover-lay, and a polymer material.

According to such an embodiment, the semiconductor package includes a circuit board, and the circuit board includes an insulating layer and a through electrode.

That is, a semiconductor package of an embodiment includes an insulating layer and a through electrode penetrating the insulating layer. The insulating layer may be a core insulating layer including a reinforcement member, and the through electrode is provided to penetrate upper and lower surfaces of the core insulating layer.

The through electrode includes a first through part adjacent to the upper surface of the insulating layer and having a first slope whose width gradually decreases toward the lower surface of the insulating layer, and a second through part adjacent to the lower surface of the insulating layer and having a second slope whose width gradually decreases toward the upper surface of the insulating layer. The first and second slopes may have slopes that are inclined in different directions along a vertical direction from the upper surface of the insulating layer toward the lower surface. Therefore, the embodiment can improve plating processability of the through electrode compared to a through electrode whose width does not change from the upper surface of the insulating layer toward the lower surface, thereby improving product yield.

As the number of semiconductor devices and/or semiconductor chiplets mounted on the circuit board increases, the area and/or thickness of the circuit board may also increase. Accordingly, a thickness of the insulating layer corresponding to the core insulating layer may increase. However, if the thickness of the core insulating layer increases, a width of a center region where the first and second slopes of the through electrode meet may be too large or too small, which may deteriorate the plating process performance.

Therefore, the embodiment improves the plating process performance in a process of plating the through electrode by ensuring that the vertical lengths of the first and second slopes of the through electrode are different from each other and further adjusting a ratio of vertical lengths of the first and second slopes.

In particular, the embodiment ensures that a ratio of the vertical lengths of the first and second slopes satisfies a range of 7:3 to 8:2. Through this, the embodiment can solve a void problem that may occur due to the width of the center region where the first slope and the second slope meet being too small. In addition, the embodiment can solve a problem of flatness in which a surface of the pad is concave because a width of the center region where the first slope and the second slope meet is too large.

Therefore, the embodiment can improve the process capability in the plating process of the through electrode by ensuring that a ratio of the vertical length of the first slope to the vertical length of the second slope satisfies a range of 7:3 to 8:2, thereby reducing the manufacturing time and improving the product yield. In addition, the embodiment can prevent the formation of voids within the through electrode, thereby preventing cracks in the through electrode due to stress caused by heat cycles, thereby improving the physical reliability of the circuit board. In addition, the embodiment can ensure the flatness of the through electrode and pad, thereby allowing the semiconductor device to be stably disposed on the circuit board. Accordingly, the embodiment can allow the semiconductor device to operate stably, and can improve the operational reliability of the semiconductor package and a product to which the semiconductor package is applied.

Meanwhile, the semiconductor package may be significantly warped in a specific direction due to the thickness of each layer of the insulating layer 110, physical properties of each layer of the insulating layer 110, the difference in the wiring density of each layer of the wiring electrode 150, and a difference in the thickness of each layer of the wiring electrode 150.

Therefore, the embodiment may adjust the vertical lengths of the first slope 141-1A and the second slope 141-2A of the first through electrode 141 in consideration of a direction in which the circuit board is warped. For example, the embodiment may allow the vertical length H2 of the first slope 141-1A to be greater than the vertical length H3 of the second slope 141-2A when the circuit board is warped in a smile shape such as a ‘∪’. For example, the embodiment may allow the vertical length H3 of the second slope 141-2A to be greater than the vertical length H2 of the first slope 141-1A when the circuit board is bent in a crying shape such as a ‘∩’.

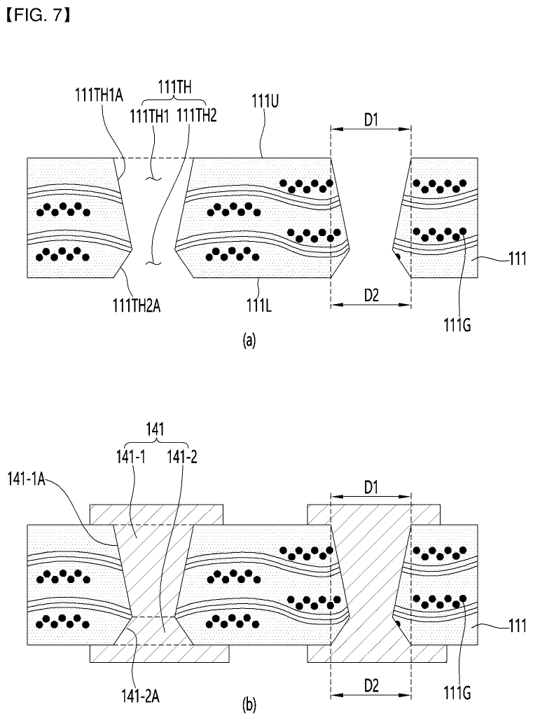

FIG. 7 is a cross-sectional view illustrating a through hole and a through electrode according to a second embodiment.

Referring to (a) of FIG. 7, the through hole 111TH provided in the first insulating layer 111 may have a first width D1 at an upper end of the first slope 111TH1A and a second width D2 at a lower end of the second slope 111TH2A.

In addition, the first width D1 at the upper end of the first slope 111TH1A of the through hole 111TH may refer to an upper width of the first hole part 111TH1 of the through hole 111TH, and the second width D2 at the lower end of the second slope 111TH2A of the through hole 111TH may refer to a lower width of the second hole part 111TH2 of the through hole 111TH.

At this time, the second embodiment allows the first width D1 and the second width D2 to have a same value. For example, the upper width and the lower width of the through hole 111TH of the second embodiment may be the same.

Referring to (b) of FIG. 7, an upper surface of the first through electrode 141 penetrating the first insulating layer 111 may have a first width D1, and a lower surface of the first through electrode 141 may have a second width D2. In this case, the upper and lower surfaces of the first through electrode 141 may have a same width.

Accordingly, the embodiment may prevent an increase in resistance caused by a difference between the first width D1 and the second width D2. Furthermore, in an embodiment, the resistance may be reduced to ½ by allowing the first width D1 and the second width D2 to be the same, and thus, the resistance of the first through electrode 141 may be reduced to improve electrical characteristics.

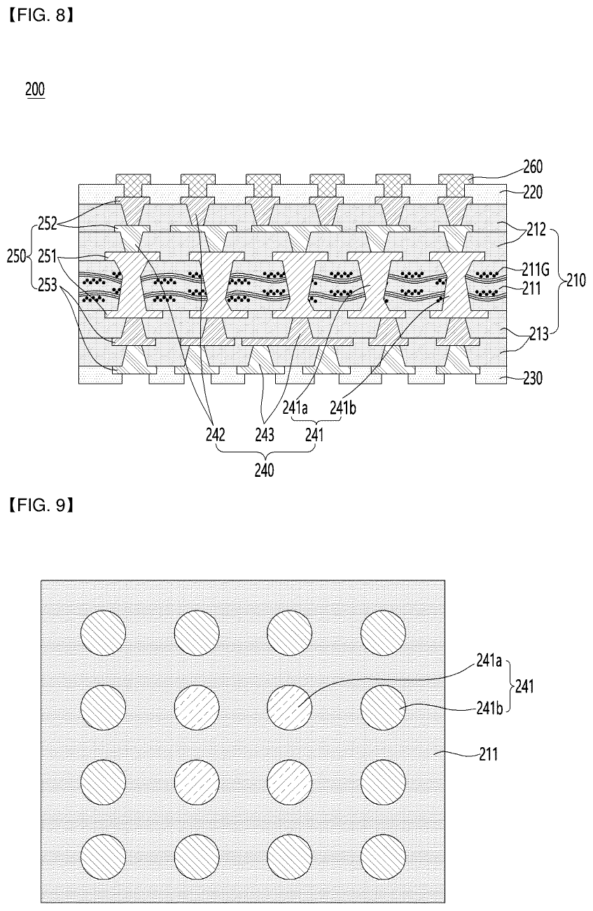

FIG. 8 is a cross-sectional view illustrating a circuit board according to a third embodiment, and FIG. 9 is a plan view illustrating a first through electrode provided in the first insulating layer of FIG. 8.

Referring to FIGS. 8 and 9, the circuit board 200 may include an insulating layer 210, a first protective layer 220, a second protective layer 230, a through electrode 240, a wiring electrode 250, and a bump electrode 260.

The insulating layer 210 may include a first insulating layer 211, a second insulating layer 212, and a third insulating layer 213.

The through electrode 240 may include a first through electrode 241 penetrating the first insulating layer 211, a second through electrode 242 penetrating the second insulating layer 212, and a third through electrode 243 penetrating the third insulating layer 213.

The wiring electrode 250 may include a first wiring electrode 251 disposed on upper and lower surfaces of the first insulating layer 211, a second wiring electrode 252 disposed on upper surface of the second insulating layer 212, and a third wiring electrode 253 disposed on lower surface of the third insulating layer 213.

The bump electrode 260 may be disposed on the second wiring electrode 252 and penetrate the first protective layer 220.

In this case, the circuit board illustrated in FIGS. 8 and 9 differs from the circuit board illustrated in FIG. 2 in the first through electrode 241 provided in the first insulating layer 211, which is the core insulating layer, and thus will be described below.

The through electrode 241 penetrates the first insulating layer 211. A plurality of through electrodes 241 are disposed in the first insulating layer 211 and are spaced apart from each other in the horizontal direction.

At this time, the through electrode 241 may include a first slope and a second slope. The first slope and the second slope of the through electrode 241 may be inclined in different directions. The first slope may be adjacent to the upper surface of the first insulating layer 211 and may gradually decrease in width as it approaches the lower surface of the first insulating layer 211. The second slope may be adjacent to the lower surface of the first insulating layer 211 and may gradually decrease in width as it approaches the upper surface of the first insulating layer 211.

Furthermore, the vertical lengths of the first slope and the second slope of the through electrode 241 may be different. For example, the vertical length of the first slope of the through electrode 241 may be different from the vertical length of the second slope of the through electrode 241.

At this time, the through electrode 241 may include a first through electrode 241a having a vertical length of the first slope greater than the vertical length of the second slope. In addition, the through electrode 241 may include a second through electrode 241b having a vertical length of the second slope greater than the vertical length of the first slope.

For example, the embodiment may arrange the first through electrode 241a and the second through electrode 241b having different vertical lengths of the first and second slopes depending on the warpage direction of the circuit board 200 at each position. Through this, the embodiment may further prevent the circuit board from warping in a specific direction, thereby further improving the physical reliability and/or electrical reliability of the semiconductor package.

For example, the first insulating layer 211 may be divided into a plurality of regions. For example, the first insulating layer 211 may include an inner region and an outer region. The outer region of the first insulating layer 211 may be an outer region adjacent to an outer surface of the first insulating layer 211 and provided along the circumferential direction of the outer surface of the first insulating layer 211. The inner region of the first insulating layer 211 may be a region inside the outer region of the first insulating layer 211.

In addition, the first through electrode 241a may be provided in the inner region of the first insulating layer 211. For example, a plurality of first through electrodes 241a may be provided in the inner region of the first insulating layer 211 and spaced apart from each other.

In addition, the second through electrode 241b may be provided in the outer region of the first insulating layer 211. The second through electrode 241b may be provided to surround the first through electrode 241a. Through this, the embodiment can further prevent the circuit board and semiconductor package from being warped in a specific direction.

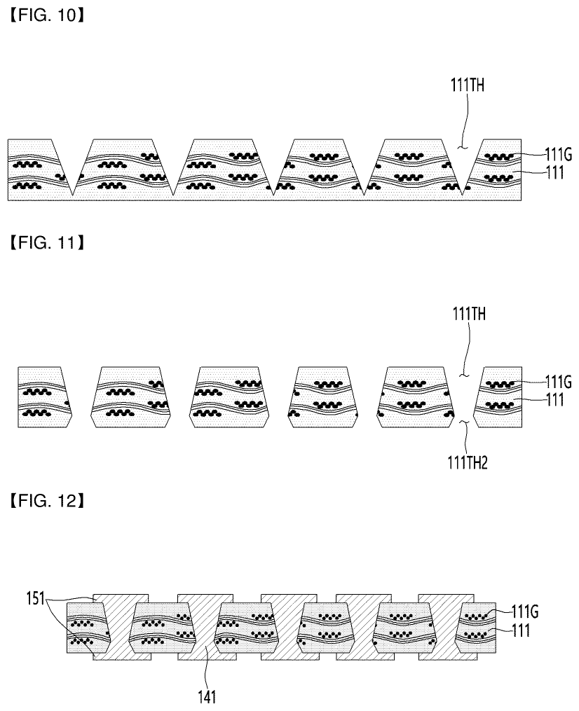

FIGS. 10 to 17 are cross-sectional views showing a method for manufacturing the circuit board shown in FIG. 2 in order of processes.

Referring to FIG. 10, the embodiment can prepare the first insulating layer 111. The first insulating layer 111 may include a reinforcement member 111G. For example, the first insulating layer 111 may be a core insulating layer. The first insulating layer 111 may utilize CCL (Copper Clad Laminate), but is not limited thereto.

Thereafter, the embodiment may perform a process of forming a first hole part 111TH1 penetrating a portion of the first insulating layer 111 from the upper surface toward the lower surface of the first insulating layer 111 by irradiating a laser beam from an upper side of the first insulating layer 111. At this time, the first hole part 111TH1 may penetrate the first insulating layer 111 or may not penetrate the first insulating layer 111. However, if the first hole part 111TH1 does not penetrate the first insulating layer 111, the embodiment may irradiate a laser beam capable of processing 90% or more of the thickness of the first insulating layer 111. Through this, the first hole part 111TH1 may be provided so as to penetrate at least 90% of the thickness of the first insulating layer 111 from the upper surface to the lower surface of the first insulating layer 111.

Referring to FIG. 11, the embodiment may perform a process of forming a second hole part 111TH2 that overlaps the first hole part 111TH1 in the vertical direction by irradiating a laser beam from a lower side of the first insulating layer 111. At this time, the process of forming the second hole part 111TH2 may be locally performed on the lower side of the first insulating layer 111. Therefore, a depth of the first hole part 111TH1 in the vertical direction and a depth of the second hole part 111TH2 in the vertical direction may be different from each other.

Through this, the embodiment can form a through hole including a first hole part 111TH1 and a second hole part 111TH2 in the first insulating layer 111. At this time, the embodiment can form a through hole including a first hole part 111TH1 having a first slope and a second hole part 111TH2 having a second slope. At this time, the vertical length of the first slope and the vertical length of the second slope may be different. That is, the region where the lower end of the first slope and the upper end of the second slope meet may be located higher or lower than a center horizontal line between the upper and lower surfaces of the first insulating layer 111.

Referring to FIG. 12, the embodiment can perform a process of forming a first through electrode 141 by filling a through hole penetrating the first insulating layer 111 with a conductive material, and a process of forming a first wiring electrode 151 on the upper and lower surfaces of the first insulating layer 111.

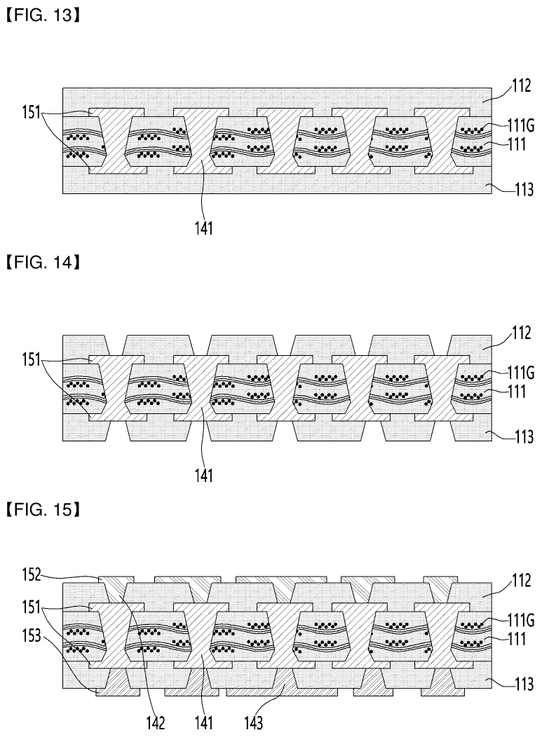

Referring to FIG. 13, the embodiment may perform a process of laminating a second insulating layer 112 on a first insulating layer 111 and a process of laminating a third insulating layer 113 under the first insulating layer 111.

Referring to FIG. 14, the embodiment may perform a process of forming a through hole penetrating at least a portion of the second insulating layer 112 and a through hole penetrating at least a portion of the third insulating layer 113.

For example, the embodiment may perform a process of forming a through hole in the second insulating layer 112 that vertically overlaps at least a portion of the first wiring electrode 151 disposed on the first insulating layer 111. In addition, the embodiment may perform a process of forming a through hole in the third insulating layer 113 that vertically overlaps at least a portion of the first wiring electrode 151 disposed under the first insulating layer 111.

Referring to FIG. 15, the embodiment may include a process of forming a second through electrode 142 by filling the through hole of the second insulating layer 112 with a conductive material, and a process of forming a second wiring electrode 152 on the upper surface of the second insulating layer 112.

Furthermore, the embodiment may include a process of forming a third through electrode 143 by filling the through hole of the third insulating layer 113 with a conductive material, and a process of forming a third wiring electrode 153 on the lower surface of the third insulating layer 113.

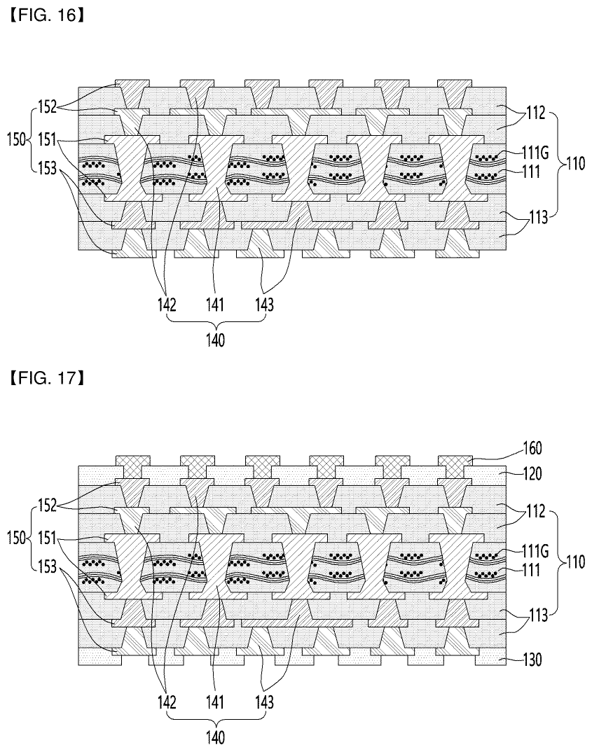

Referring to FIG. 16, the embodiment may repeat the processes of FIGS. 13 to 15 to manufacture a multilayer substrate.

Referring to FIG. 17, the embodiment may include a process of laminating a first protective layer 120 on the second insulating layer 112 and a process of laminating a second protective layer 130 under the third insulating layer 113. In addition, the embodiment may perform a process of forming an opening in the first protective layer 120 and the second protective layer 130. In addition, the embodiment may perform a process of forming a bump electrode 160 on the second wiring electrode 152 exposed through the opening in the first protective layer 120.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a core insulating layer including an upper surface and a lower surface;
an upper insulating layer disposed on the core insulating layer;
a lower insulating layer disposed under the core insulating layer; and
a through electrode penetrating the upper and lower surfaces of the core insulating layer,
wherein the through electrode includes:
a first through part disposed adjacent to the upper surface of the core insulating layer and having a first slope whose width gradually decreases toward the lower surface of the core insulating layer; and
a second through part disposed adjacent to the lower surface of the core insulating layer and having a second slope whose width gradually decreases toward the upper surface of the core insulating layer,
wherein a vertical length of the first slope is different from a vertical length of the second slope, and
wherein a difference between a width of an upper surface of the first through part and a width of a lower surface of the second through part is smaller than a difference between the vertical length of the first slope and the vertical length of the second slope.

2. The circuit board of claim 1, wherein a horizontal distance between an upper end of the first slope at one side of the through electrode and a lower end of the second slope at the one side of the through electrode is smaller than a vertical distance from a center horizontal line between the upper and lower surfaces of the through electrode to a region where the first slope and the second slope meet.

3. The circuit board of claim 1, wherein the through electrode has a smallest width in a region where the first slope of the first through part and the second slope of the second through part meet.

4. The circuit board of claim 1, wherein the width of the lower surface of the first through part is the same as the width of the upper surface of the second through part.

5. The circuit board of claim 1, wherein a slope angle of the first slope and a slope angle of the second slope are not constant, and
wherein the vertical length of the first slope is greater than the vertical length of the second slope.

6. The circuit board of claim 1, wherein a region where the first slope of the first through part and the second slope of the second through part meet is closer to the lower surface of the core insulating layer than to the upper surface of the core insulating layer.

7. The circuit board of claim 1, wherein a ratio of the vertical length of the first slope to the vertical length of the second slope is 7:3 to 8:2.

8. The circuit board of claim 7, wherein the core insulating layer is an insulating layer having a largest thickness among a plurality of insulating layers.

9. The circuit board of claim 8, wherein the core insulating layer has a thickness in a range of 100 μm to 700 μm.

10. The circuit board of claim 8, wherein the core insulating layer includes a reinforcement member.

11. The circuit board of claim 3, wherein a difference between widths of upper and lower surfaces of the first through part and a difference between widths of upper and lower surfaces of the second through part is smaller than the vertical distance from the center horizontal line between the upper and lower surfaces of the through electrode to the region where the first slope and the second slope meet.

12. The circuit board of claim 1, wherein the first slope and the second slope are inclined in different directions.

13. The circuit board of claim 10, further comprising:
an upper through electrode penetrating the upper insulating layer; and
a lower through electrode penetrating the lower insulating layer,
wherein the upper through electrode has a third slope whose width gradually decreases from an upper surface of the upper insulating layer toward a lower surface of the upper insulating layer.

14. The circuit board of claim 13, wherein the lower through electrode has a fourth slope whose width gradually decreases from a lower surface of the lower insulating layer toward an upper surface of the lower insulating layer.

15. The circuit board of claim 13, further comprising:
a connection member embedded in the upper insulating layer,
wherein the connection member includes at least one of an inorganic bridge and an organic bridge.

16. The circuit board of claim 10, further comprising:
a plurality of semiconductor devices disposed on the upper insulating layer,
wherein at least a portion of each of the plurality of semiconductor devices overlaps the connection member in a vertical direction.

17. A circuit board comprising:
a core insulating layer including an upper surface and a lower surface;
an upper insulating layer disposed on the upper surface of the core insulating layer;
a lower insulating layer disposed under the lower surface of the core insulating layer; and
a through electrode penetrating the upper and lower surfaces of the core insulating layer,
wherein the through electrode includes a first slope disposed adjacent to the upper surface of the core insulating layer and having a width that gradually decreases toward the lower surface of the core insulating layer, and a second slope disposed adjacent to the lower surface of the core insulating layer and having a width that gradually decreases toward the upper surface of the core insulating layer,
wherein a vertical length of the first slope is different from a vertical length of the second slope, and
wherein the through electrode includes a first through electrode having a vertical length of the first slope greater than a vertical length of the second slope, and a second through electrode having a vertical length of the first slope smaller than a vertical length of the second slope and spaced apart from the first through electrode in a horizontal direction.

18. The circuit board of claim 17, wherein one of the first and second through electrodes is provided in a plurality of numbers in an inner region of the core insulating layer, and
wherein the other one of the first and second through electrodes is provided in a plurality of numbers in an outer region surrounding the inner region of the core insulating layer along a circumferential direction of the upper surface of the core insulating layer.
